(19) United States
(12) Patent Application Publication
(10) Pub. No.: US 2026/0163309 A1
(43) Pub. Date: Jun. 11, 2026

(54) CONNECTOR ASSEMBLY WITH HOLDING ARM TO FIX LIGHT GUIDE PIPE

(71) Applicant: DONGGUAN XUNTAO ELECTRONIC CO.,LTD., Dongguan City (CN)

(72) Inventors: Bin HUANG, Dongguan City (CN); Chenhui ZENG, Dongguan City (CN); Kunlin YAO, Dongguan City (CN); Hongji CHEN, Dongguan City (CN)

(73) Assignee: DONGGUAN XUNTAO ELECTRONIC CO.,LTD., Dongguan City (CN)

(21) Appl. No.: 19/300,472

(22) Filed: Aug. 14, 2025

(30) Foreign Application Priority Data
Dec. 6, 2024 (CN) 202411798589.4

(51) Int. Cl. H01R 13/717; H01R 13/6594

(52) U.S. Cl. CPC H01R 13/7172; H01R 13/6594

(57) ABSTRACT

A connector assembly includes an electrical connector, a shielding cage, and a light guide pipe. The electrical connector includes a housing, a conductive terminal mounted to the housing, and a cable electrically connected to the conductive terminal. The shielding cage is configured to be mounted to a circuit board. The shielding cage includes a receiving cavity. The shielding cage is provided with a holding arm. The light guide pipe includes a first pipe body portion, a second pipe body portion and a first connecting portion. The first pipe body portion and the second pipe body portion are located on two sides of the cable, respectively. The first connecting portion defines a mounting slot. The holding arm is at least partially inserted into the mounting slot so as to fix the light guide pipe, thereby simplifying the fixing structure.

### CROSS-REFERENCE TO RELATED APPLICATION

This patent application claims priority of a Chinese Patent Application No. 202411798589.4, filed on Dec. 6, 2024 and titled “CONNECTOR ASSEMBLY”, the entire content of which is incorporated herein by reference.

### TECHNICAL FIELD

The present disclosure relates to a connector assembly, which belongs to the technical field of connectors.

### BACKGROUND

A connector assembly in the related art normally includes an electrical connector, a shielding cage enclosing the electrical connector, and a light guide pipe. The electrical connector includes an insulating body, a plurality of conductive terminals mounted to the insulating body, and a metal shell enclosing the insulating body. The plurality of conductive terminals includes a plurality of signal terminals. The light guide pipe is installed on the shielding cage to display the working status of the electrical connector through a light source. However, as the space utilization of the connector assembly continues to improve, how to use an improved fixing structure to fix the light guide pipe is a technical problem to be solved by those skilled in the art.

### SUMMARY

The present disclosure adopts the following technical solution: a connector assembly, including: an electrical connector, the electrical connector including: a housing, the housing defining a receiving slot; a plurality of conductive terminals, the plurality of conductive terminals being mounted to the housing; and a cable, the cable being electrically connected to the conductive terminals; a shielding cage, the shielding cage being configured to be mounted to a circuit board, the shielding cage defining a receiving cavity communicating with the receiving slot along a first direction; the receiving cavity and the receiving slot being configured to jointly receive a mating connector along the first direction; the cable passing out of the shielding cage along the first direction; the shielding cage being provided with a holding arm; and a light guide pipe, the light guide pipe including a first pipe body portion, a second pipe body portion, and a first connecting portion connecting the first pipe body portion and the second pipe body portion; the first pipe body portion and the second pipe body portion being located on two sides of the cable, respectively; the first connecting portion defining a mounting slot; the holding arm being at least partially inserted into the mounting slot so as to fix the light guide pipe.

### BRIEF DESCRIPTION OF DRAWINGS

FIG. 1 is a perspective schematic view of a connector assembly in accordance with an embodiment of the present disclosure;

FIG. 2 is a perspective view of FIG. 1 from another angle;

FIG. 3 is a partial enlarged view of circled part B in FIG. 2;

FIG. 4 is a perspective view of FIG. 2 from another angle;

FIG. 5 is a front view of FIG. 1;

FIG. 6 is a rear view of FIG. 1;

FIG. 7 is a right view of FIG. 1;

FIG. 8 is a top view of FIG. 1;

FIG. 9 is a partially exploded perspective view of FIG. 2, in which one light guide pipe is separated;

FIG. 10 is a partial enlarged view of circled portion C in FIG. 9;

FIG. 11 is a partially exploded perspective view of FIG. 9 from another angle;

FIG. 12 is a partial enlarged view of circled portion D in FIG. 11;

FIG. 13 is a further exploded perspective view of FIG. 9;

FIG. 14 is an exploded perspective view of FIG. 13 from another angle;

FIG. 15 is an exploded perspective view of the shielding cage in FIG. 13;

FIG. 16 is an exploded perspective view of FIG. 15 from another angle;

FIG. 17 is an exploded perspective view of FIG. 15 from another angle;

FIG. 18 is a schematic perspective view of an electrical connector in accordance with an embodiment of the present disclosure;

FIG. 19 is a partially exploded perspective view of FIG. 18;

FIG. 20 is a partially exploded perspective view of FIG. 19 from another angle;

FIG. 21 is an exploded perspective view of a first module and a second module in FIG. 19;

FIG. 22 is an exploded perspective view of FIG. 21 from another angle;

FIG. 23 is a top view of the first module and the second module when they are misaligned;

FIG. 24 is a bottom view of the first module and the second module when they are misaligned;

FIG. 25 is a front view after removing an outer insulating housing in FIG. 19;

FIG. 26 is a partially exploded perspective view of FIG. 21;

FIG. 27 is a partially exploded perspective view of the first module in FIG. 26;

FIG. 28 is a partially exploded perspective view of FIG. 27 from another angle;

FIG. 29 is a partially exploded perspective view of the second module in FIG. 26;

FIG. 30 is a partially exploded perspective view of FIG. 29 from another angle;

FIG. 31 is a partial enlarged view of frame part E in FIG. 27;

FIG. 32 is a partial enlarged view of frame portion F in FIG. 29;

FIG. 33 is a further partial perspective exploded view after removing a first conductive housing, a first insulating fixing block and a first ground sheet in FIG. 27;

FIG. 34 is a further partial perspective exploded view after removing a second conductive housing, a second insulating fixing block and a second ground sheet in FIG. 29;

FIG. 35 is a partial enlarged view of circled portion H in FIG. 33;

FIG. 36 is a partial enlarged view of circled portion I in FIG. 34;

FIG. 37 is a partially exploded perspective view of FIG. 33 from another angle;

FIG. 38 is a partially exploded perspective view of FIG. 34 from another angle;

FIG. 39 is a further partially exploded perspective view of FIG. 33;

FIG. 40 is a further partially exploded perspective view of FIG. 34;

FIG. 41 is a partially exploded perspective view of FIG. 39 from another angle;

FIG. 42 is a further exploded perspective view of FIG. 39;

FIG. 43 is a further exploded perspective view of FIG. 40;

FIG. 44 is a perspective view of part of the first module;

FIG. 45 is a perspective view of part of the second module;

FIG. 46 is a partially exploded perspective view of part of the first module and part of the second module in FIG. 39 and FIG. 40 in another embodiment;

FIG. 47 is a partially exploded perspective view of FIG. 46 from another angle;

FIG. 48 is a schematic cross-sectional view taken along line J-J in FIG. 5;

FIG. 49 is a partial enlarged view of frame part K in FIG. 48;

FIG. 50 is a schematic cross-sectional view taken along line L-L in FIG. 5;

FIG. 51 is a partial enlarged view of frame part N in FIG. 50;

FIG. 52 is a schematic cross-sectional view taken along line O-O in FIG. 8; and

FIG. 53 is a partial enlarged view of frame part P in FIG. 52.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

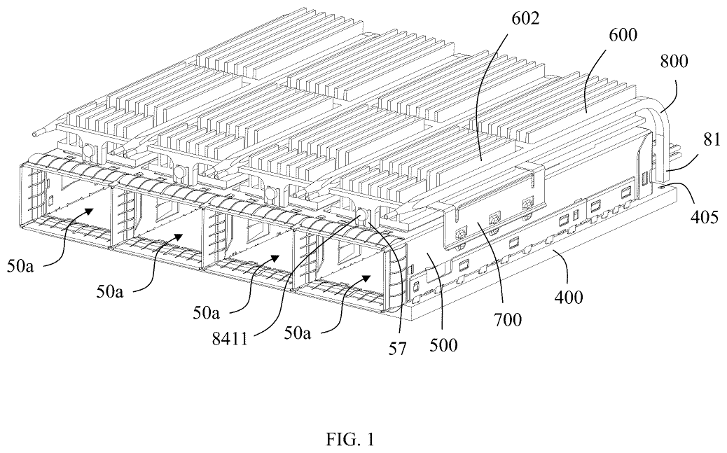

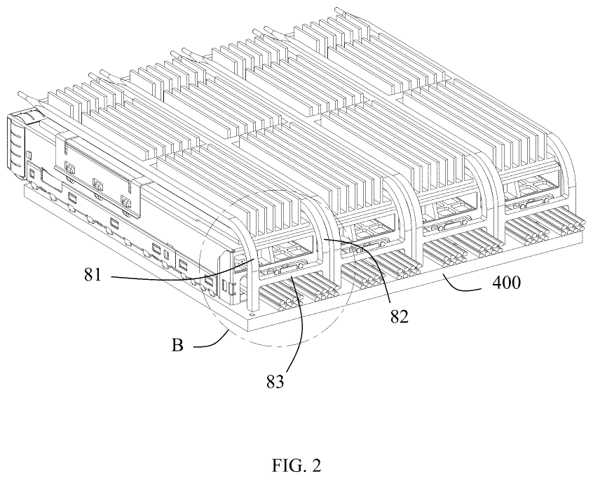

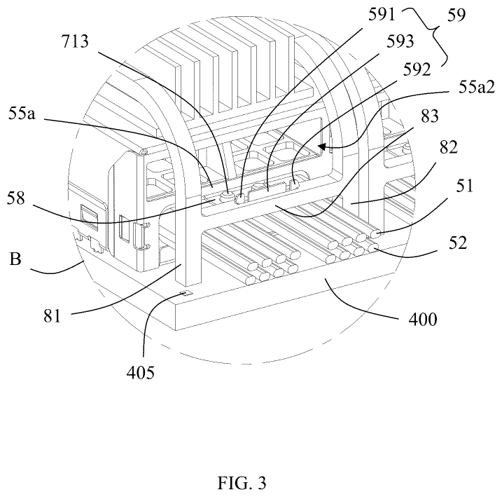

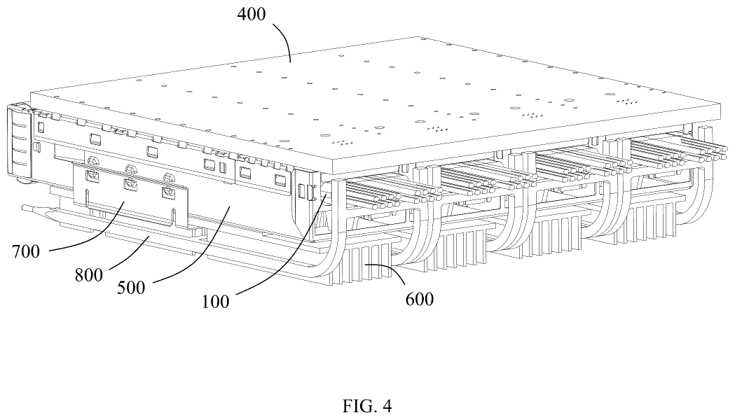

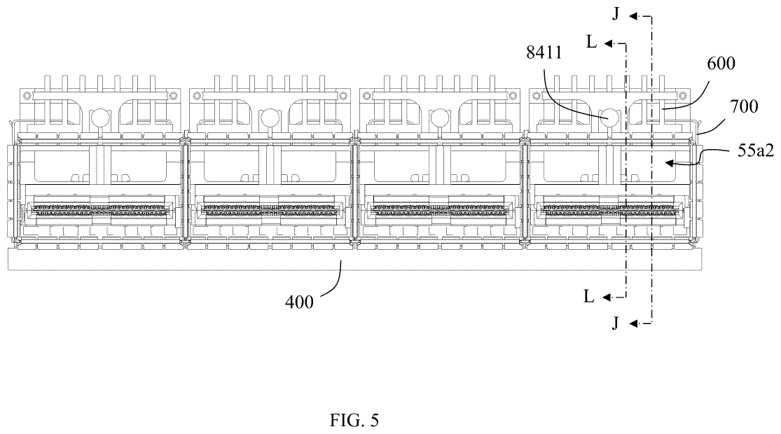

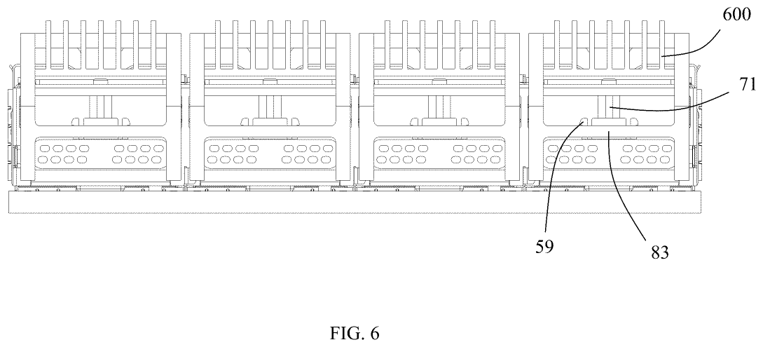

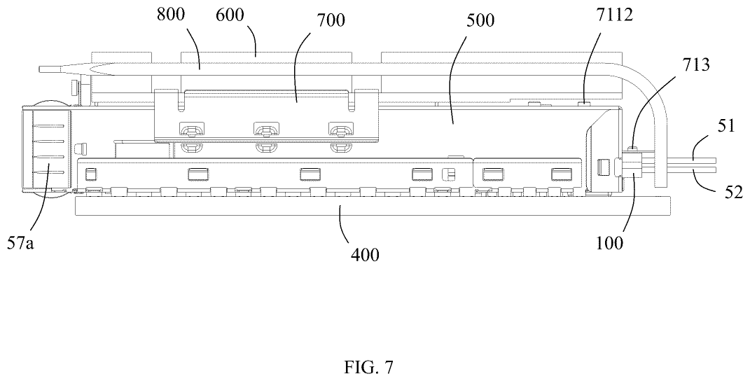

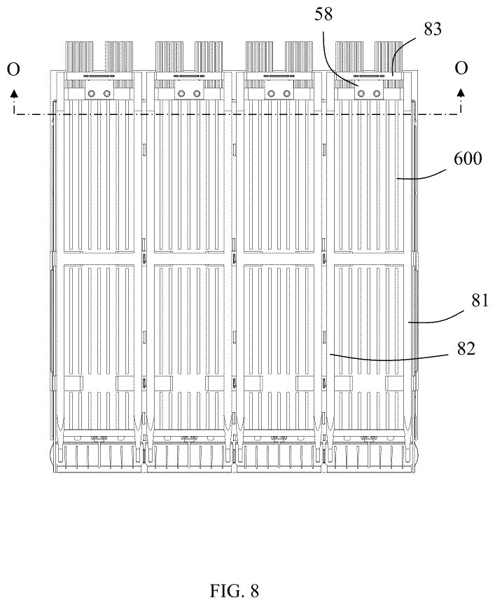

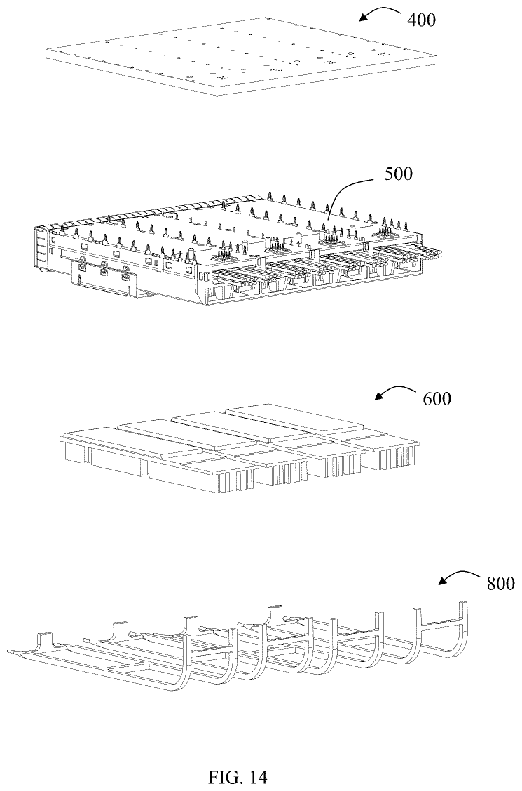

Referring to FIG. 1 to FIG. 14, a first embodiment of the present disclosure discloses a connector assembly including an electrical connector 100, a circuit board 400 and a first mating connector configured to be at least partially inserted into the electrical connector 100. In the illustrated embodiment of the present disclosure, the electrical connector 100 is an OSFP (Octal Small Form-factor Pluggable) receptacle connector. More specifically, in the illustrated embodiment of the present disclosure, the electrical connector 100 is a receptacle connector. Correspondingly, the first mating connector is an OSFP plug connector. Of course, it is understandable to those skilled in the art that the electrical connector 100 can also be an SFP (Small Form-factor Pluggable) receptacle connector, a QSFP (Quad Small Form-factor Pluggable) receptacle connector, a QSFP-DD (Quad Small Form-factor Pluggable-Double Density) receptacle connector, an SFP-DD (Small Form-factor Pluggable-Double Density) receptacle connector or a DSFP (Dual Chanel Small Form-factor Pluggable) receptacle connector, etc. Correspondingly, the first mating connector is an SFP plug connector, a QSFP plug connector, a QSFP-DD plug connector, an SFP-DD plug connector or a DSFP plug connector, etc. It is understandable to those skilled in the art that the basic structure of the above types of the electrical connectors is regulated by corresponding association standards, and will not be described in detail here. Of course, it is understandable to those skilled in the art that the electrical connector 100 can also be other types of electrical connectors, including but not limited to USB connectors, HDMI connectors, DisplayPort connectors, RJ45 connectors, Thunderbolt connectors, etc.

Referring to FIG. 1 to FIG. 13, in the illustrated embodiment of the present disclosure, the circuit board 400 includes a plurality of first mounting holes 401 and a plurality of second mounting holes 402. The plurality of first mounting holes 401 are disposed in a first row along a first direction A1-A1 (for example, a front-rear direction). The plurality of second mounting holes 402 are disposed in a second row parallel to the first row along the first direction A1-A1. Besides, the circuit board 400 is further provided with a plurality of first conductive holes 403, a plurality of second conductive holes 404, a first light-emitting element 405 and a second light-emitting element 406. The first light-emitting element 405 and the second light-emitting element 406 include but are not limited to LED light emitters.

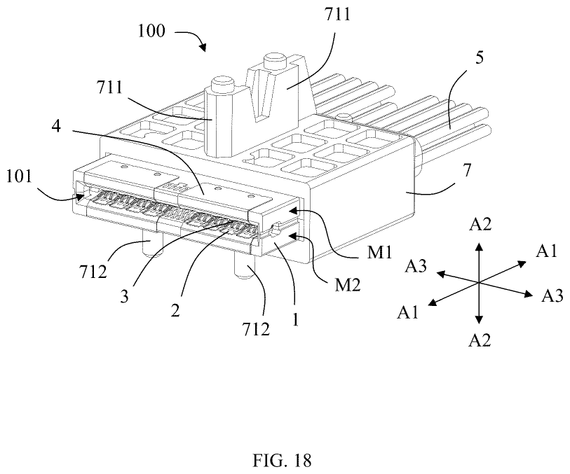

The mating connector includes a mating module, such as a tongue plate. The tongue plate includes an upper surface, a lower surface, a plurality of first contact pads exposed on the upper surface and a plurality of second contact pads exposed to the lower surface. Referring to FIG. 18, in the illustrated embodiment of the present disclosure, the electrical connector 100 defines a receiving slot 101 for at least partially receiving the first mating connector. To simplify the description of the specific embodiments of the present disclosure, an insertion and extraction direction of the first mating connector and the electrical connector 100 is a first direction A1-A1 (for example, a front-rear direction); a thickness direction of the receiving slot 101 is a second direction A2-A2 (for example, a top-bottom direction); a width direction of the receiving slot 101 is a third direction A3-A3 (for example, a left-right direction). Each two of the first direction A1-A1, the second direction A2-A2 and the third direction A3-A3 are perpendicular to each other.

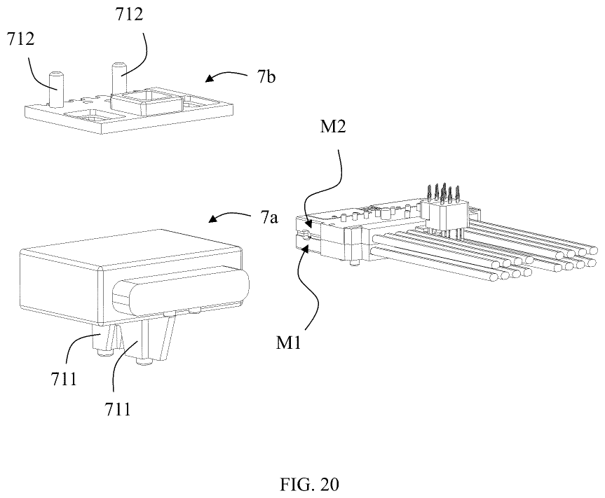

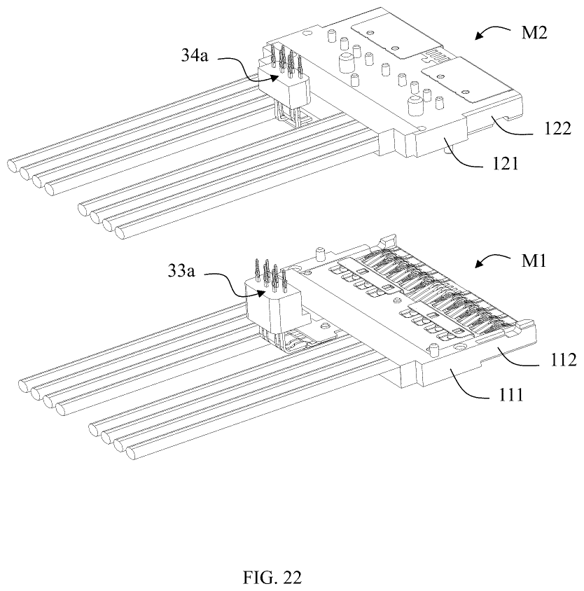

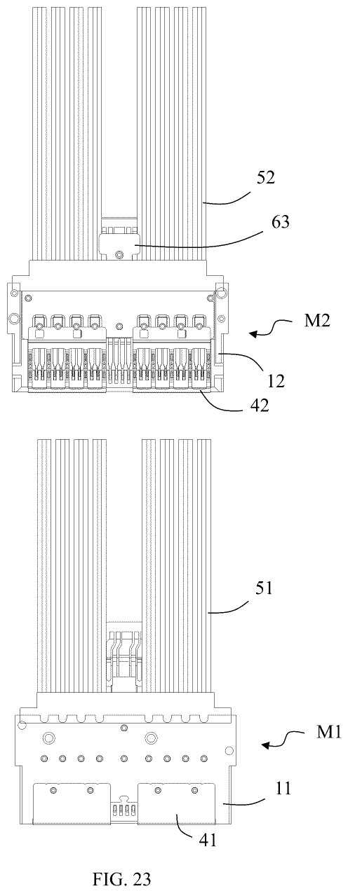

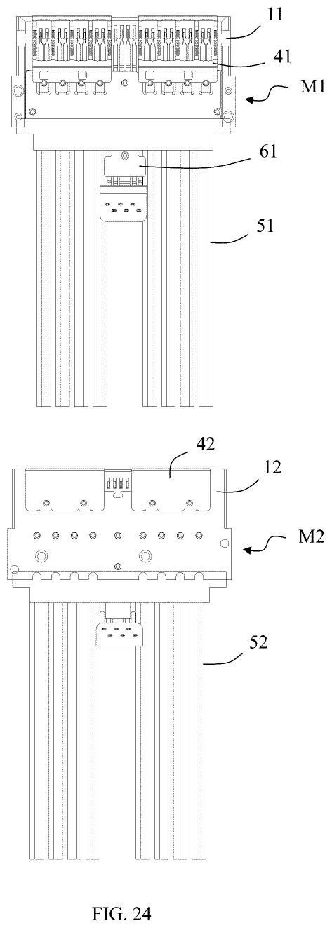

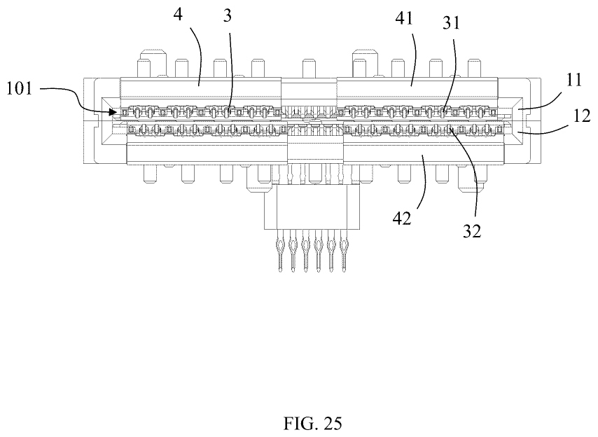

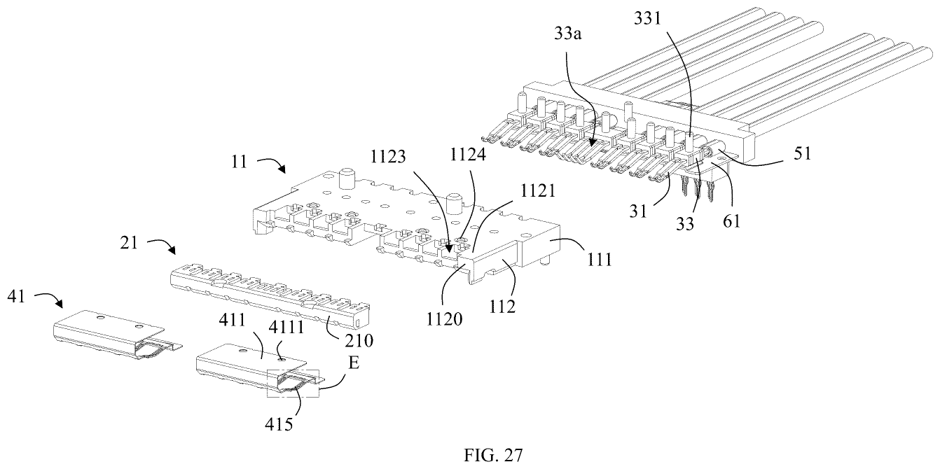

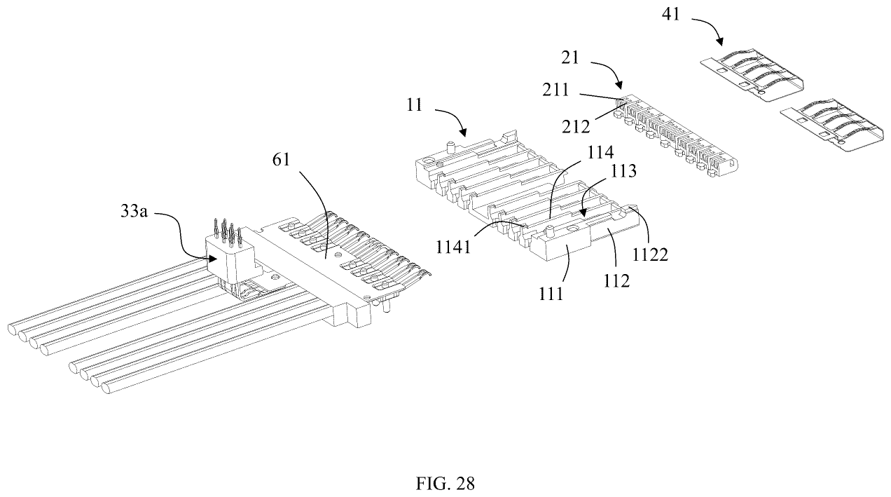

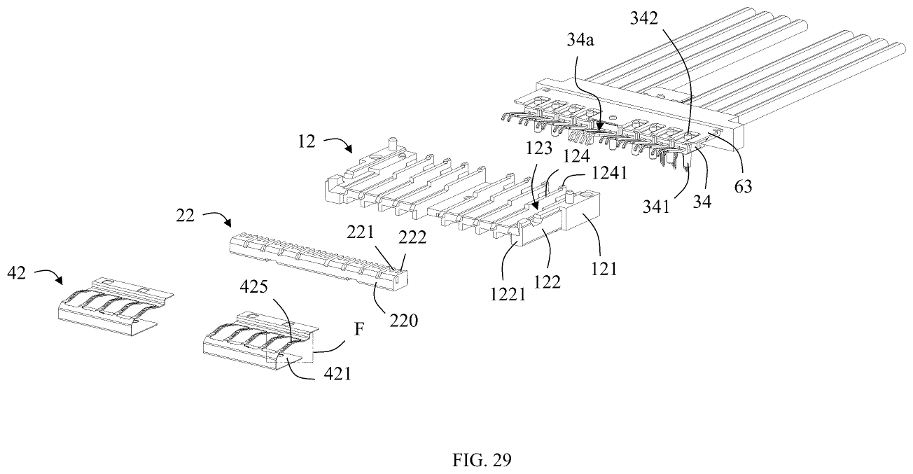

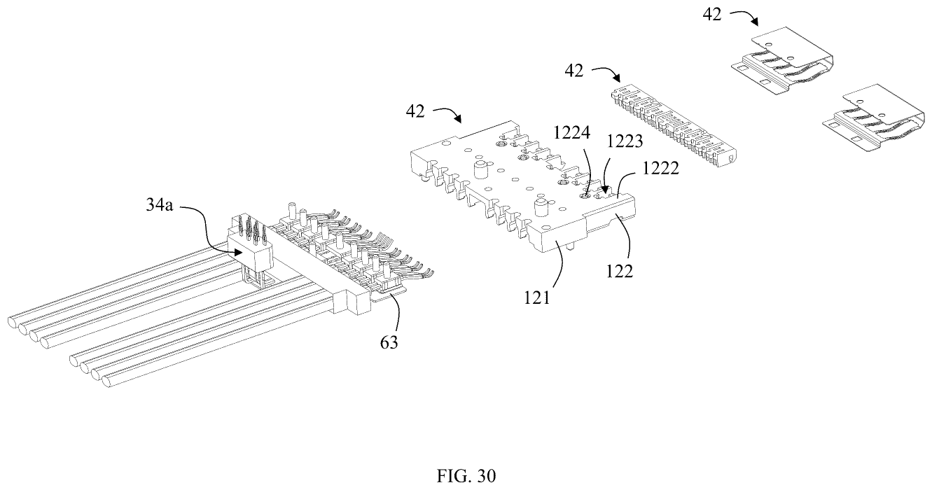

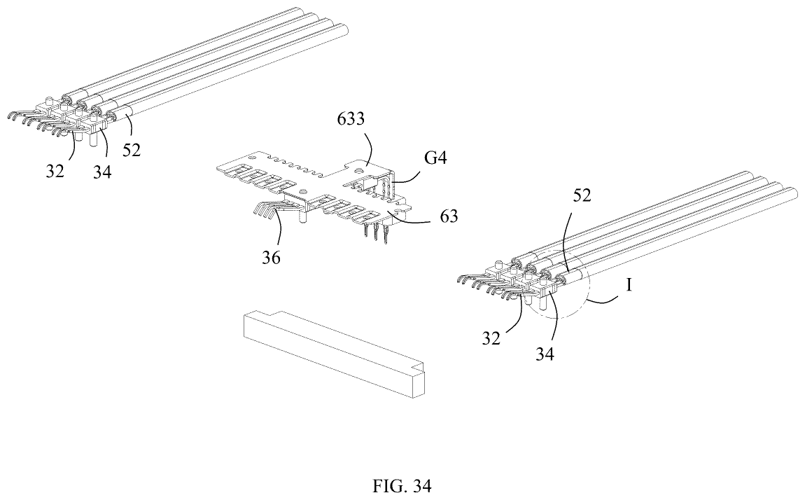

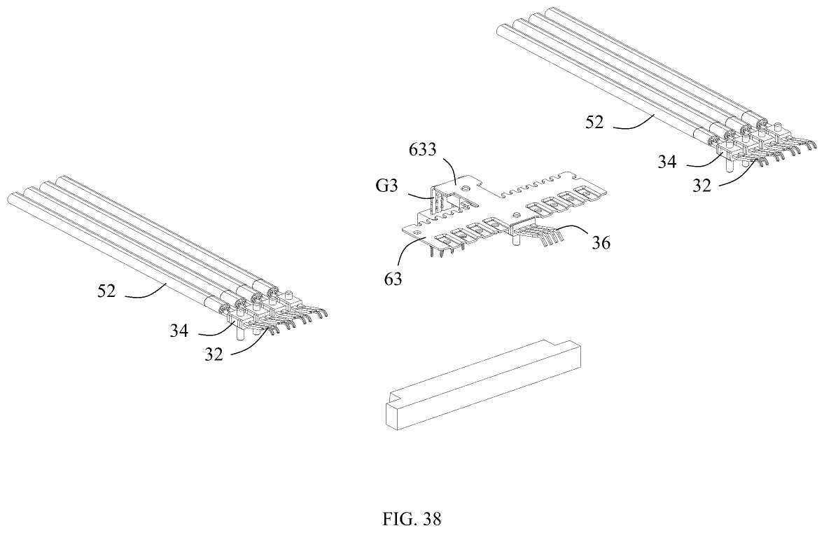

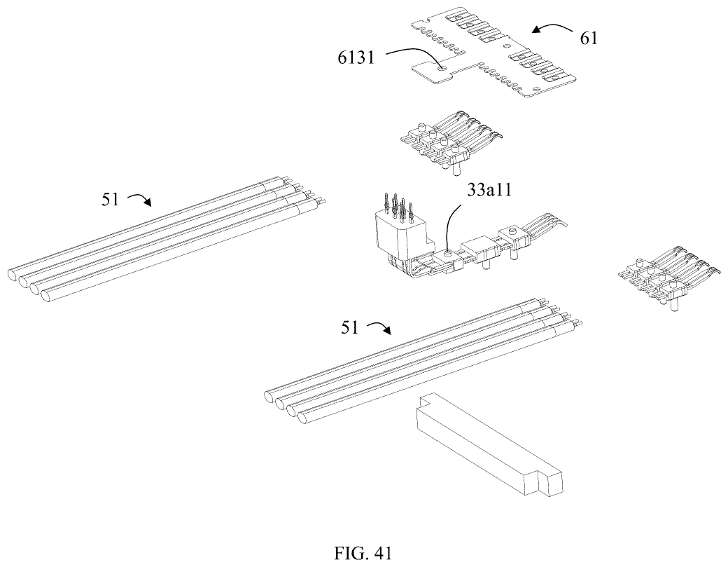

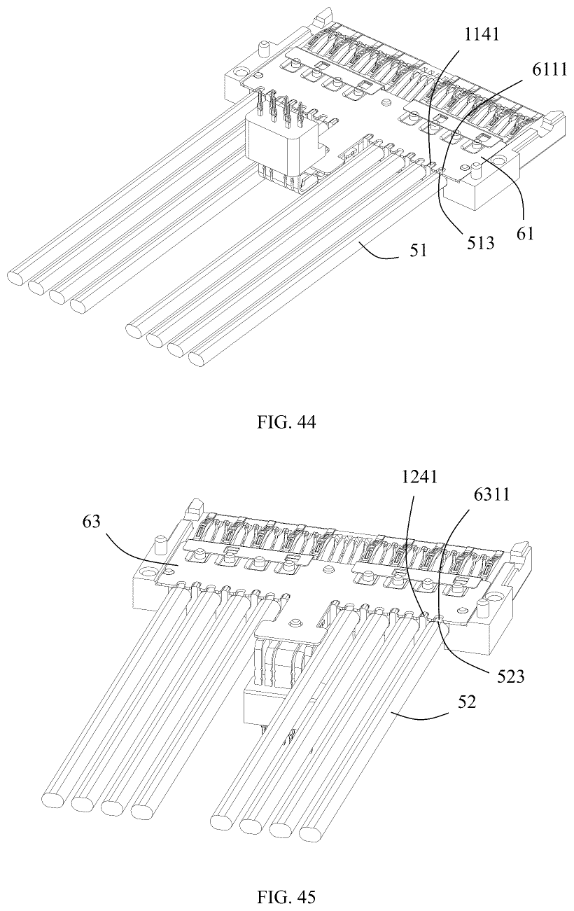

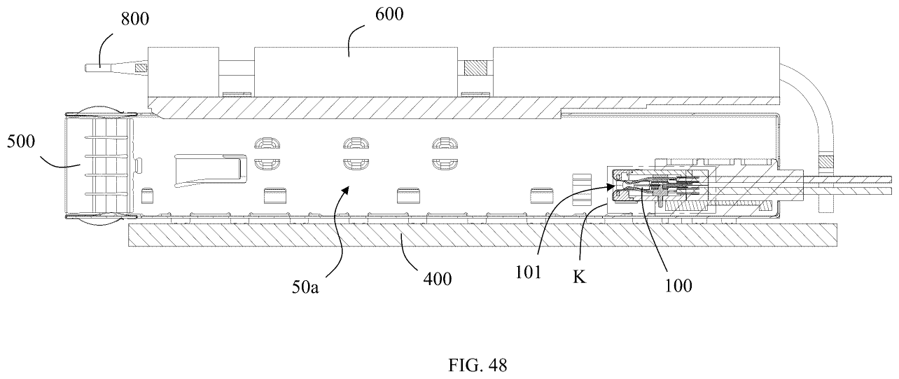

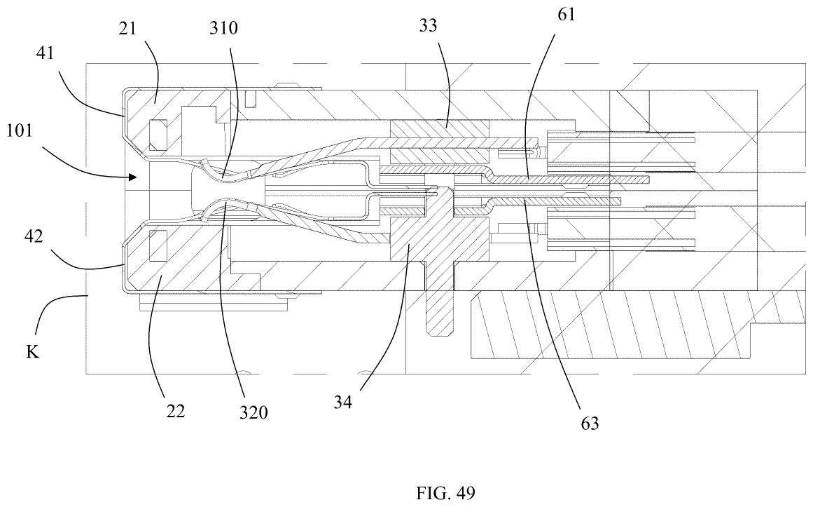

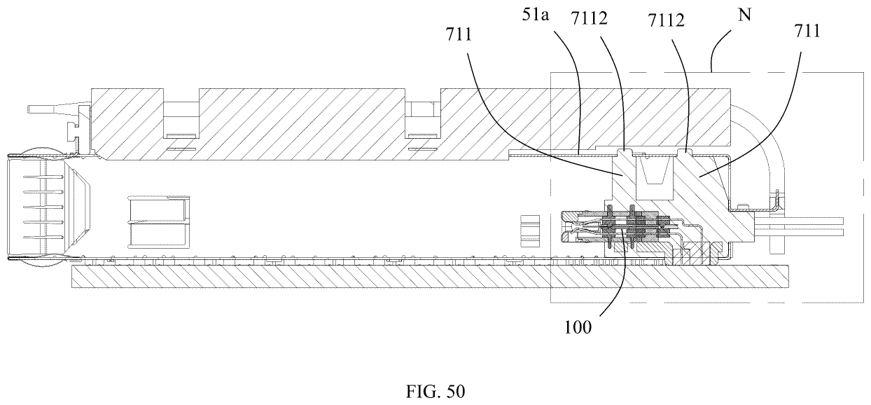

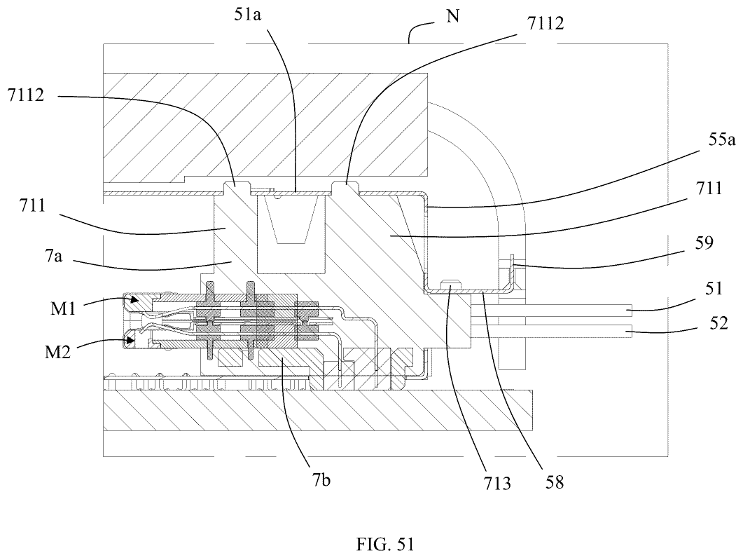

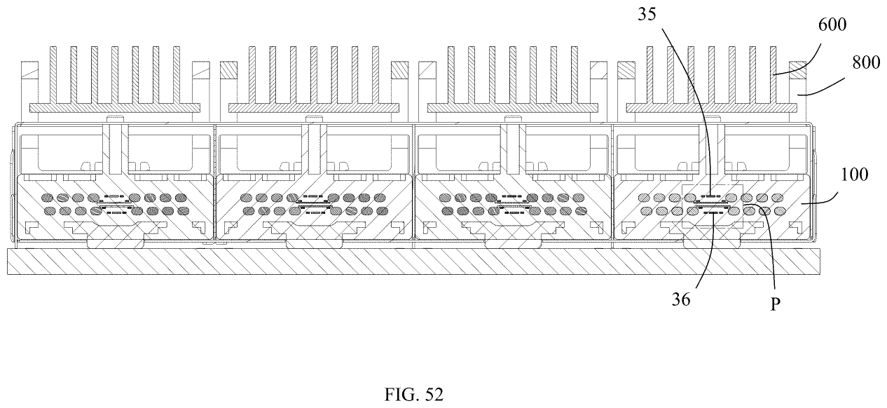

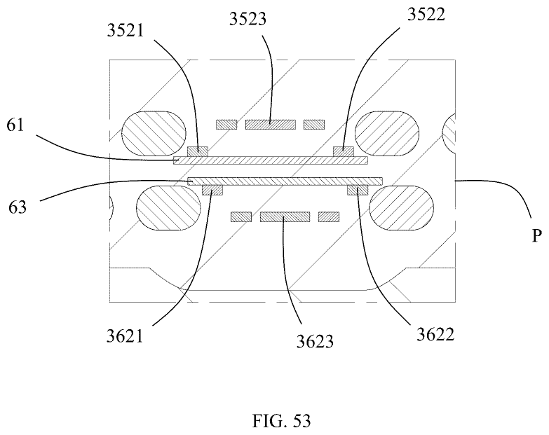

Referring to FIG. 18 to FIG. 53, in the illustrated embodiment of the present disclosure, the electrical connector 100 includes a first module M1, a second module M2, and an outer insulating housing 7 fixed on the first module M1 and the second module M2. The first module M1 and the second module M2 are separately provided and fixed together. In one embodiment of the present disclosure, the outer insulating housing 7 is made of insulating material and is over-molded on the first module M1 and the second module M2 so as to be combined with the first module M1 and the second module M2 as a whole. Specifically, in the illustrated embodiment of the present disclosure, the outer insulating housing 7 includes a first outer insulating housing 7a and a second outer insulating housing 7b.

Each of the first outer insulating housing 7a and the second outer insulating housing 7b includes at least one positioning protrusion 71. In the illustrated embodiment of the present disclosure, the at least one positioning protrusion 71 on the first outer insulating housing 7a includes a plurality of first positioning protrusions 711. The at least one positioning protrusion 71 on the second outer insulating housing 7b includes a plurality of second positioning protrusions 712. In the illustrated embodiment of the present disclosure, two first positioning protrusions 711 are provided and they are spaced apart along the first direction A1-A1. Two second positioning protrusions 712 are provided and they are spaced apart along the third direction A3-A3. With this arrangement, the two first positioning protrusions 711 and the two second positioning protrusions 712 can prevent the relative position of the electrical connector 100 and the shielding cage 500 from changing after assembly. The first positioning protrusions 711 are opposite to the second positioning protrusions 712.

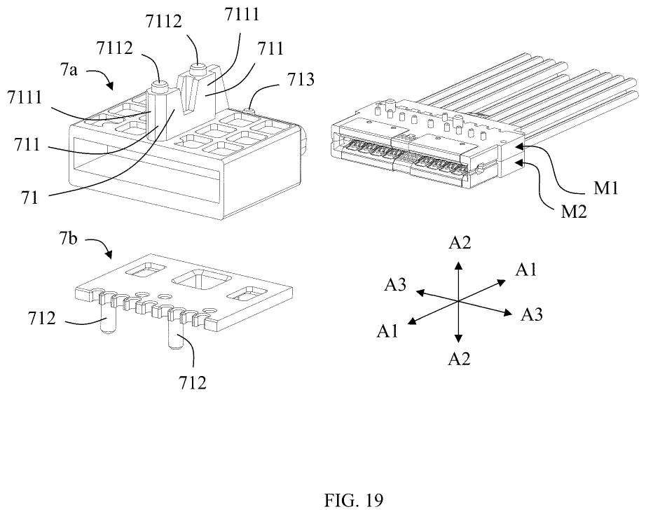

Specifically, referring to FIG. 19, the first positioning protrusion 711 includes a support portion 7111 and a positioning portion 7112 which is connected to the support portion 7111 and located at an end of the first positioning protrusion 711 along the second direction A2-A2. In the illustrated embodiment of the present disclosure, both the positioning portion 7112 and the second positioning protrusion 712 are of cylindrical-shaped configurations. Besides, in order to increase the structural strength of the support portion 7111, the support portion 7111 is designed to be relatively thicker than the positioning portion 7112.

In one embodiment of the present disclosure, the electrical connector 100 includes a housing, an insulating fixing block 2 fixed to the housing, a plurality of conductive terminals 3 installed to the housing and a plurality of cables 5 connected to the conductive terminals 3.

In an embodiment of the present disclosure, the housing is a conductive housing 1. The conductive housing 1 is a metal housing made of metal material so as to further improve the shielding effect and improve the quality of signal transmission. In another embodiment of the present disclosure, the conductive housing 1 may also be a composite housing formed by electroplating a metal material on an insulating material. The composite housing can also improve the shielding effect and improve the quality of signal transmission.

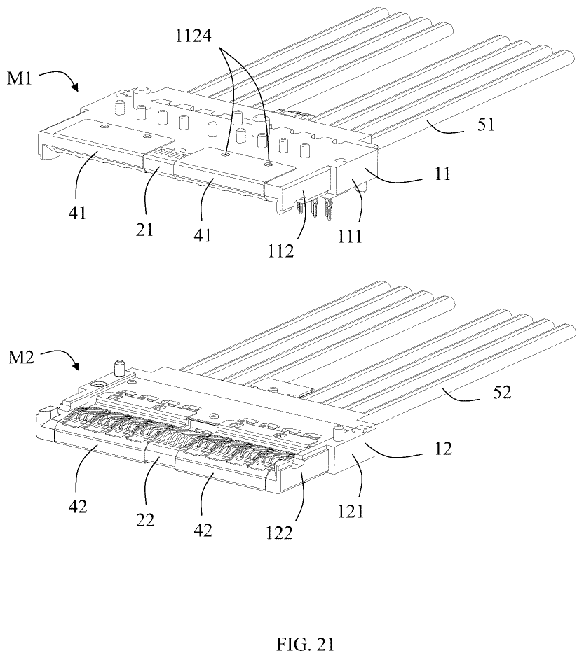

As shown in FIG. 21 to FIG. 30, in an embodiment of the present disclosure, the conductive housing 1 includes a first conductive housing 11 and a second conductive housing 12. The first conductive housing 11 and the second conductive housing 12 are fixed together. For example, after the first conductive housing 11 and the second conductive housing 12 are assembled, they are fixed together for example by welding or soldering or other methods. In the illustrated embodiment of the present disclosure, the first conductive housing 11 of the first module M1 and the second conductive housing 12 of the second module M2 are separately arranged and fixed together to jointly form the receiving slot 101.

In an embodiment of the present disclosure, the first conductive housing 11 includes a first base portion 111, a first protruding portion 112 extending forwardly from the first base portion 111 and a plurality of first terminal module installation slots 113 extending through the first base portion 111 and the first protruding portion 112 along the first direction A1-A1. The first protruding portion 112 includes a second upper surface 1121, a second lower surface 1122, and a plurality of first filling grooves 1123 extending upwardly through the second upper surface 1121 along the second direction A2-A2. The first filling grooves 1123 extend forwardly through a first front end surface 1120 of the first protruding portion 112 along the first direction A1-A1. The first protruding portion 112 further includes a plurality of first positioning posts 1124 protruding upwardly beyond the second upper surface 1121 along the second direction A2-A2.

The plurality of first terminal module installation slots 113 are spaced apart along the third direction A3-A3. The first conductive housing 11 includes a plurality of first partition walls 114 disposed at intervals along the third direction A3-A3. Two adjacent first terminal module installation slots 113 are separated by a corresponding first partition wall 114 along the third direction A3-A3. In other words, each first terminal module installation slot 113 is surrounded by four walls of the first conductive housing 11 on a length corresponding to the corresponding first partition wall 114, thereby improving the shielding effect. With this arrangement, each first terminal module installation slot 113 is relatively independent, thereby reducing signal crosstalk and improving the quality of data transmission. Each first partition wall 114 is provided with a first positioning block 1141 raised along the third direction A3-A3. The first positioning block 1141 is located at an end away from the first front end surface 1120.

In an embodiment of the present disclosure, the second conductive housing 12 includes a second base portion 121, a second protruding portion 122 extending forwardly from the second base portion 121 and a plurality of second terminal module installation slots 123 extending through the second base portion 121 and the second protruding portion 122 along the first direction A1-A1. The second protruding portion 122 includes a fourth upper surface 1221, a fourth lower surface 1222, and a plurality of second filling grooves 1223 extending downwardly through the fourth lower surface 1222. The second filling grooves 1223 extend forwardly through a second front end surface 1220 of the second protruding portion 122. The second protruding portion 122 further includes a plurality of second positioning posts 1224 protruding downwardly beyond the second lower surface 1122.

In an embodiment of the present disclosure, the plurality of second terminal module installation slots 123 are arranged at intervals along the third direction A3-A3. The second conductive housing 12 includes a plurality of second partition walls 124 disposed at intervals along the third direction A3-A3. Two adjacent second terminal module installation slots 123 are separated by corresponding second partition walls 124 along the third direction A3-A3. In other words, each second terminal module installation slot 123 is surrounded by four walls of the second conductive housing 12 on a length corresponding to the second partition wall 124, thereby improving the shielding effect. With this arrangement, each second terminal module installation slot 123 is relatively independent, thereby reducing signal crosstalk and improving the quality of data transmission. Each second partition wall 124 is provided with a second positioning block 1241 raised along the third direction A3-A3. The second positioning block 1241 is located at an end away from the second front end surface 1220.

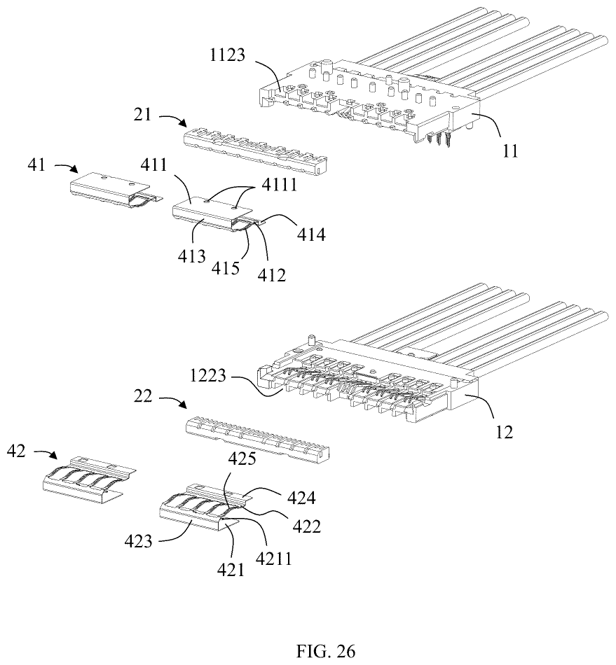

Referring to FIG. 26 to FIG. 30, in the illustrated embodiment of the present disclosure, the insulating fixing block 2 includes a first insulating fixing block 21 and a second insulating fixing block 22. The first insulating fixing block 21 is fixed in the first filling grooves 1123. The second insulating fixing block 22 is fixed in the second filling grooves 1223. Preferably, in order to increase the bonding force between the first insulating fixing block 21 and the first conductive housing 11, the first insulating fixing block 21 is molded in the first filling grooves 1123. Similarly, in order to increase the bonding force between the second insulating fixing block 22 and the second conductive housing 12, the second insulating fixing block 22 is molded in the second filling grooves 1223.

The first insulating fixing block 21 defines a plurality of first slits 211 and a plurality of second slits 212, in which adjacent first slit 211 and second slit 212 form a group and communicate with a corresponding first terminal module installation slot 113. The first insulating fixing block 21 further includes a first front surface 210 which is coplanar with the first front end surface 1120 of the first protruding portion 112.

Similarly, the second insulating fixing block 22 defines a plurality of third slits 221 and a plurality of fourth slits 222. Adjacent third slit 221 and fourth slit 222 form a group and communicate with a corresponding second terminal module installation slot 123. The second insulating fixing block 22 includes a second front surface 220 which is coplanar with the second front end surface 1220 of the second protruding portion 122.

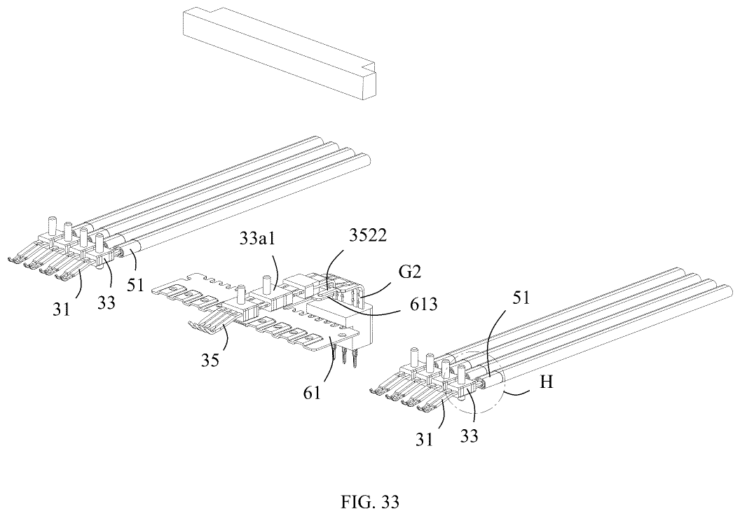

As shown in FIG. 33 to FIG. 47, the plurality of conductive terminals 3 include a plurality of first conductive terminals 31, a plurality of second conductive terminals 32, a plurality of first board-end terminals 35 and a plurality of second board-end terminals 36. Each first conductive terminal 31 includes a first fixing portion 311 extending along the first direction A1-A1, a first contact arm 310 extending forwardly from a front end of the first fixing portion 311, and a first tail portion 313 extending backwardly from a rear end of the first fixing portion 311. The first contact arm 310 includes a first contact portion 3101 that extends into the receiving slot 101. The first contact portions 3101 are configured to be in contact with first signal contact pads of the tongue plate. In the illustrated embodiment of the present disclosure, the first tail portions 313 extend backwardly and horizontally to be electrically connected to first cables 51.

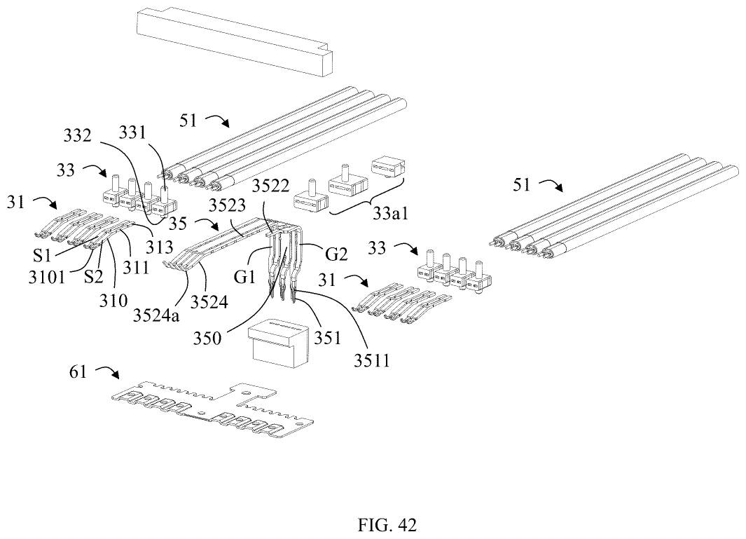

Referring to FIG. 42, in the illustrated embodiment of the present disclosure, the plurality of first conductive terminals 31 are divided into a plurality of groups. Each group of first conductive terminals 31 includes a first signal terminal S1 and a second signal terminal S2 located adjacent to the first signal terminal S1. Preferably, the first signal terminal S1 and the second signal terminal S2 in each group of first conductive terminals 31 form a differential pair to improve signal transmission speed, thereby being suitable for high-speed signal transmission.

In the illustrated embodiment of the present disclosure, the electrical connector 100 further includes a first holding block 33 fixed on the first signal terminal S1 and the second signal terminal S2 of each group of first conductive terminals 31. In an embodiment of the present disclosure, the first signal terminal S1 and the second signal terminal S2 are insert-molded with the first holding block 33, so as to form an integrated first terminal module 31a. The first contact portions 3101 of the first signal terminal S1 and the second signal terminal S2 in each first terminal module 31a are configured to be in contact with the first signal contact pads of the first mating connector, respectively.

In the illustrated embodiment of the present disclosure, the first holding block 33 is fixed to the middle portions of the first fixing portions 311 of the first signal terminal S1 and the second signal terminal S2. The first holding block 33 is installed and fixed in the first terminal module installation slot 113 so that the first conductive terminal 31 does not come into contact with the first conductive housing 11 and cause a short circuit. In the illustrated embodiment of the present disclosure, the first holding block 33 includes a first protruding post 331 protruding along the third direction A3-A3 and a first positioning protruding post 332 protruding along the third direction A3-A3. The first protruding post 331 and the first positioning protruding post 332 protrude in opposite directions. The first protruding post 331 is used for positioning with a corresponding through hole of the first conductive housing 11 and the first protruding post 331 extends through the first conductive housing 11.

Similarly, each second conductive terminal 32 includes a second fixing portion 321 extending along the first direction A1-A1, a second contact arm 320 extending forwardly from a front end of the second fixing portion 321, and a second tail portion 323 extending backwardly from a rear end of the second fixing portion 321. The second contact arm 320 includes a second contact portion 3201 that extends into the receiving slot 101. The second contact portions 3201 are configured to be in contact with the second signal contact pads of the tongue plate. In the illustrated embodiment of the present disclosure, the second tail portions 323 extend backwardly and horizontally from the second fixing portions 321 to be electrically connected to second cables 52.

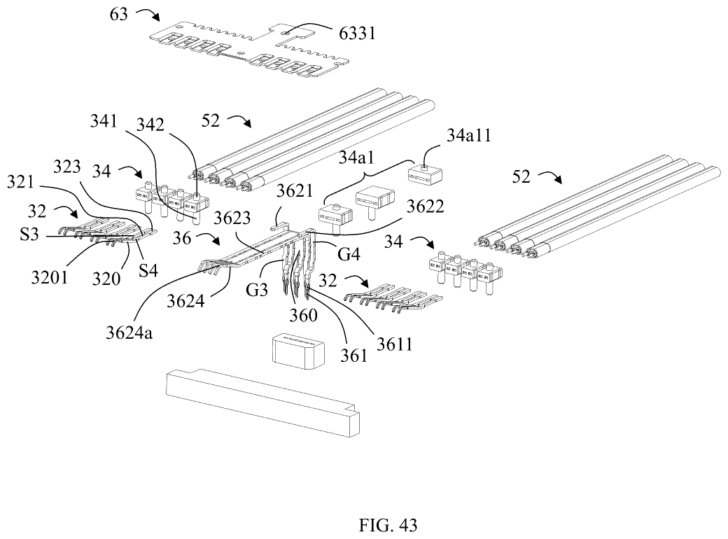

Referring to FIG. 43, in the illustrated embodiment of the present disclosure, the plurality of second conductive terminals 32 are divided into a plurality of groups, and each group of second conductive terminals 32 includes a third signal terminal S3 and a fourth signal terminal S4 located adjacent to the third signal terminal S3. Preferably, the third signal terminal S3 and the fourth signal terminal S4 in each group of second conductive terminals 32 form a differential pair to improve signal transmission speed, thereby being suitable for high-speed signal transmission.

In the illustrated embodiment of the present disclosure, the electrical connector 100 further includes a second holding block 34 fixed on the third signal terminal S3 and the fourth signal terminal S4 of each group of second conductive terminals 32. In one embodiment of the present disclosure, the third signal terminal S3 and the fourth signal terminal S4 are insert-molded with the second holding block 34 to form an integrated second terminal module 32a. The second contact portions 3201 of the third signal terminal S3 and the fourth signal terminal S4 in each second terminal module 32a are configured to be in contact with the second signal contact pads of the first mating connector.

In the illustrated embodiment of the present disclosure, the second holding block 34 is fixed to the middle portions of the second fixing portions 321 of the third signal terminal S3 and the fourth signal terminal S4. The second holding block 34 is installed and fixed in the second terminal module installation slot 123 so that the second conductive terminal 32 does not come into contact with the second conductive housing 12 to cause a short circuit. In the illustrated embodiment of the present disclosure, the second holding block 34 includes a second protruding post 341 protruding along the third direction A3-A3 and a second positioning protruding post 342 protruding along the third direction A3-A3. The second protruding post 341 and the second positioning protruding post 342 protrude in opposite directions. The second protruding post 341 is used for positioning with a corresponding through hole of the second conductive housing 12, and the second protruding post 341 extends through the second conductive housing 12.

In the illustrated embodiment of the present disclosure, the electrical connector 100 further includes a first non-high-speed terminal module 33a and a second non-high-speed terminal module 34a. The first non-high-speed terminal module 33a includes at least one first insulating block 33a1, the first board-end terminals 35 fixed to the first insulating block 33a1, and a first mounting block 37 fixed on the first board-end terminals 35. It is understandable to those skilled in the art that the first board-end terminals 35 include but are not limited to non-high-speed signal terminals, power terminals, and the like.

In the illustrated embodiment of the present disclosure, the first board-end terminals 35 include a first ground terminal G1, a second ground terminal G2 and at least one first board-end additional terminal 350 located between the first ground terminal G1 and the second ground terminal G2. Each first board-end terminal 35 includes a first mounting tail portion 351 configured to be mounted to the circuit board 400. In the illustrated embodiment of the present disclosure, each first mounting tail portion 351 defines a first mounting through hole 3511, so that the first mounting tail portion 351 is configured to be inserted into the first conductive hole 403 of the circuit board 400 in an elastically deformable manner to achieve electrical conduction with the circuit board 400.

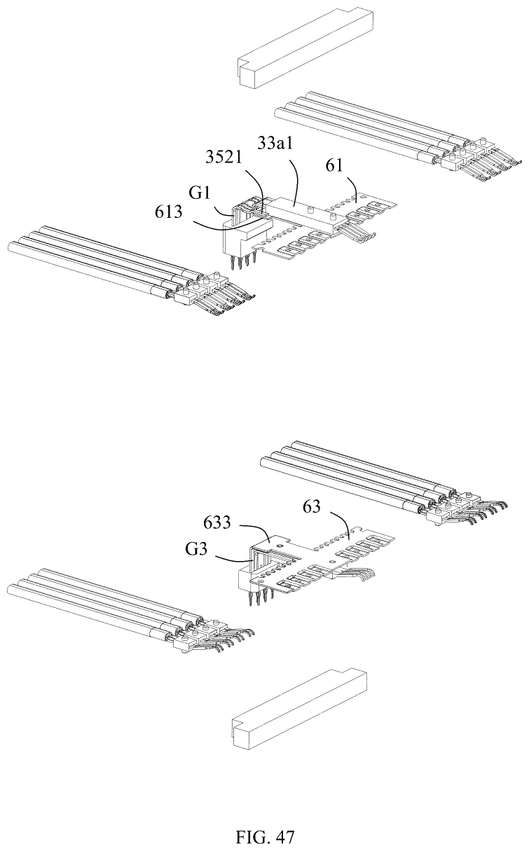

Besides, the first ground terminal G1 further includes a first abutting portion 3521 (as shown in FIG. 47). The first abutting portion 3521 extends along the first direction A1-A1. The first mounting tail portion 351 of the first ground terminal G1 extends along the second direction A2-A2. The first mounting tail portion 351 of the first ground terminal G1 is perpendicular to the first abutting portion 3521 of the first ground terminal G1.

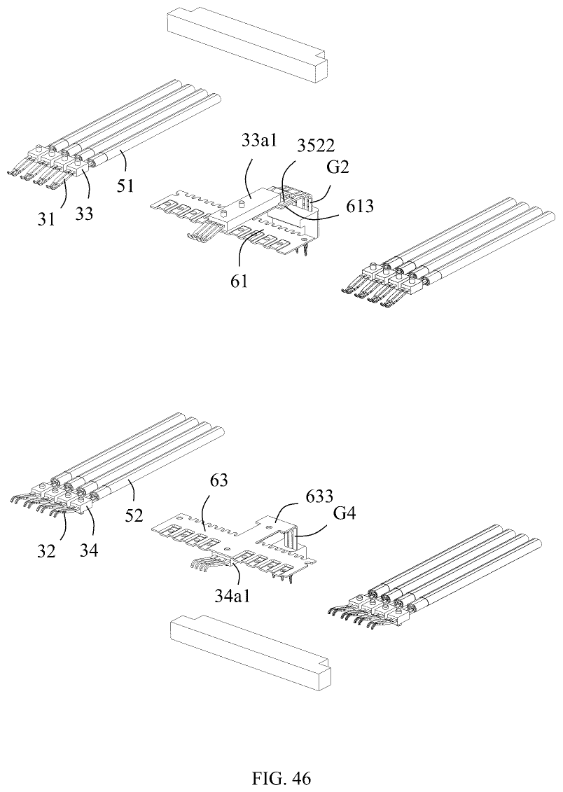

Similarly, the second ground terminal G2 further includes a second abutting portion 3522 (as shown in FIG. 46). The second abutting portion 3522 extends along the first direction A1-A1. The first mounting tail portion 351 of the second ground terminal G2 extends along the second direction A2-A2. The first mounting tail portion 351 of the second ground terminal G2 is perpendicular to the second abutting portion 3522 of the second ground terminal G2.

Referring to FIG. 42, each first board-end additional terminal 350 includes a first extension portion 3523 and a first additional contact arm 3524 connected to the first extension portion 3523. The first additional contact arm 3524 includes a first additional abutting portion 3524a protruding into the receiving slot 101. The first extension portion 3523 extends along the first direction A1-A1. The first mounting tail portion 351 of the first board-end additional terminal 350 extends along the second direction A2-A2. The first mounting tail portion 351 of the first board-end additional terminal 350 is perpendicular to the first extension portion 3523 of the first board-end additional terminal 350.

In the illustrated embodiment of the present disclosure, the first abutting portion 3521, the second abutting portion 3522, and the first extension portion 3523 are parallel to one another. A length of the first extension portion 3523 along the first direction A1-A1 is greater than a length of the first abutting portion 3521 along the first direction A1-A1, and the length of the first extension portion 3523 along the first direction A1-A1 is greater than a length of the second abutting portion 3522 along the first direction A1-A1. Neither the first ground terminal G1 nor the second ground terminal G2 is provided with any elastic contact arm protruding into the receiving slot 101 and configured to be electrically connected to the mating connector. In other words, neither the first ground terminal G1 nor the second ground terminal G2 is provided with the first additional contact arm 3524 similar to the first board-end additional terminal 350.

In the illustrated embodiment of the present disclosure, the first abutting portion 3521 and the second abutting portion 3522 are located at a first height along the second direction A2-A2. The first extension portion 3523 is located at a second height along the second direction A2-A2. The first height is different from the second height.

In the illustrated embodiment of the present disclosure, the first extension portion 3523 of the first board-end additional terminal 350 is partially insert-molded with the first insulating block 33a1. The first additional contact arm 3524 extends out of the first insulating block 33a1. The first insulating block 33a1 is provided with at least one first positioning protruding post 33a11.

The first ground terminal G1, the second ground terminal G2 and the first board-end additional terminal 350 are all insert-molded with the first mounting block 37 to be integrated into a whole. The first mounting tail portions 351 of the first ground terminal G1, the second ground terminal G2 and the first board-end additional terminal 350 all extend beyond the first mounting block 37.

Similarly, as shown in FIG. 43, the second non-high-speed terminal module 34a includes at least one second insulating block 34a1, a plurality of second board-end terminals 36 fixed to the second insulating block 34a1, and a second mounting block 38 fixed to the second board-end terminals 36. It is understandable to those skilled in the art that the second board-end terminals 36 include, but are not limited to, non-high-speed signal terminals, power terminals, and the like.

In the illustrated embodiment of the present disclosure, the second board-end terminal 36 includes a third ground terminal G3, a fourth ground terminal G4, and at least one second board-end additional terminal 360 located between the third ground terminal G3 and the fourth ground terminal G4. Each second board-end terminal 36 includes a second mounting tail portion 361 configured to be mounted to the circuit board 400. In the illustrated embodiment of the present disclosure, each second mounting tail portion 361 defines a second mounting through hole 3611, so that the second mounting tail portion 361 is able to be inserted into the second conductive hole 404 of the circuit board 400 in an elastically deformable manner so as to achieve electrical conduction with the circuit board 400.

Besides, the third ground terminal G3 further includes a third abutting portion 3621. The third abutting portion 3621 extends along the first direction A1-A1. The second mounting tail portion 361 of the third ground terminal G3 extends along the second direction A2-A2. The second mounting tail portion 361 of the third ground terminal G3 is perpendicular to the third abutting portion 3621 of the third ground terminal G3.

Similarly, the fourth ground terminal G4 further includes a fourth abutting portion 3622. The fourth abutting portion 3622 extends along the first direction A1-A1. The second mounting tail portion 361 of the fourth ground terminal G4 extends along the second direction A2-A2. The second mounting tail portion 361 of the fourth ground terminal G4 is perpendicular to the fourth abutting portion 3622 of the fourth ground terminal G4.

The second board-end additional terminal 360 includes a second extension portion 3623 and a second additional contact arm 3624 connected to the second extension portion 3623. The second additional contact arm 3624 includes a second additional abutting portion 3624a protruding into the receiving slot 101. The second extension portion 3623 extends along the first direction A1-A1. The second mounting tail portion 361 of the second board-end additional terminal 360 extends along the second direction A2-A2. The second mounting tail portion 361 of the second board-end additional terminal 360 is perpendicular to the second extension portion 3623 of the second board-end additional terminal 360.

In the illustrated embodiment of the present disclosure, the third abutting portion 3621, the fourth abutting portion 3622 and the second extension portion 3623 are parallel to one another. A length of the second extension portion 3623 along the first direction A1-A1 is greater than a length of the third abutting portion 3621 along the first direction A1-A1, and the length of the second extension portion 3623 along the first direction A1-A1 is greater than a length of the fourth abutting portion 3622 along the first direction A1-A1. Neither the third ground terminal G3 nor the fourth ground terminal G4 is provided with any elastic contact arm protruding into the receiving slot 101 and configured to be electrically connected to the mating connector. In other words, neither the third ground terminal G3 nor the fourth ground terminal G4 is provided with the second additional contact arm 3624 similar to the second board-end additional terminal 360.

In the illustrated embodiment of the present disclosure, the third abutting portion 3621 and the fourth abutting portion 3622 are located at a third height along the second direction A2-A2. The second extension portion 3623 is located at a fourth height along the second direction A2-A2. The third height is different from the fourth height.

In the illustrated embodiment of the present disclosure, the second extension portion 3623 of the second board-end additional terminal 360 is partially insert-molded with the second insulating block 34a1. The second additional contact arm 3624 extends out of the second insulating block 34a1. The second insulating block 34a1 is provided with at least one second positioning protruding post 34a11.

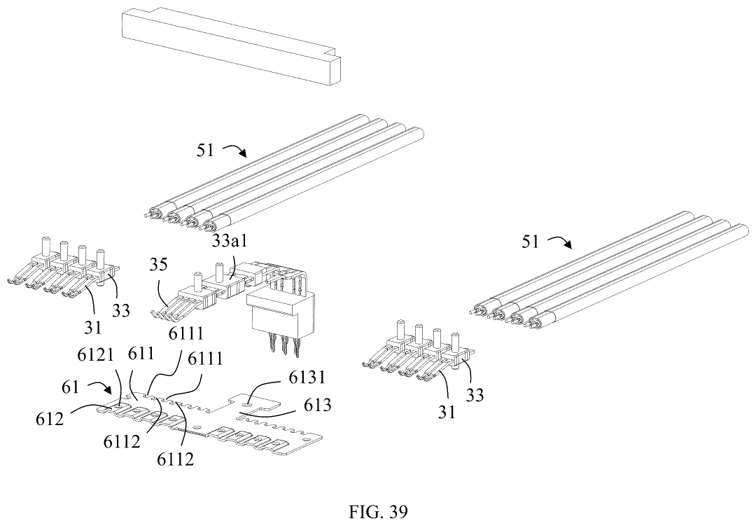

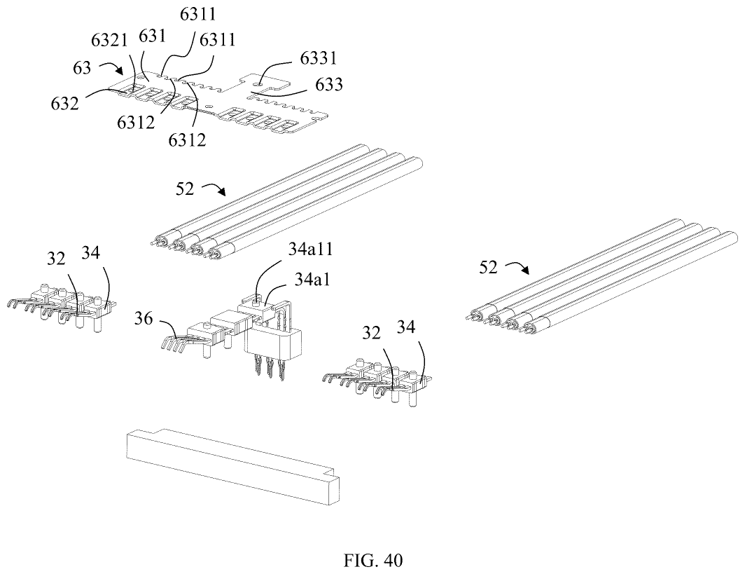

As shown in FIG. 39 and FIG. 40, in an embodiment of the present disclosure, a plurality of first insulating blocks 33a1 and a plurality of second insulating blocks 34a1 are provided, respectively. Referring to FIG. 46 and FIG. 47, in another embodiment of the present disclosure, only one first insulating block 33a1 and only one second insulating block 34a1 are provided.

The third ground terminal G3, the fourth ground terminal G4 and the second board-end additional terminals 360 are all insert-molded with the second mounting block 38 to be integrated into a whole. The second mounting tail portions 361 of the third ground terminal G3, the fourth ground terminal G4 and the second board-end additional terminals 360 all extend beyond the second mounting block 38.

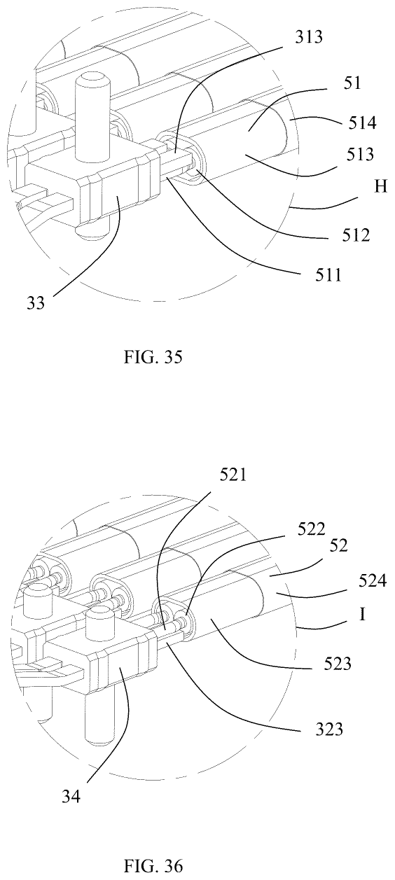

Referring to FIG. 35, in the illustrated embodiment of the present disclosure, the first cable 51 includes a first core 511, a first insulator 512 wrapped around the first core 511, a first shielding layer 513 (such as a shielding braid) wrapped around the first insulator 512, and a first insulation skin 514 wrapped around the first shielding layer 513.

Similarly, as shown in FIG. 36, the second cable 52 includes a second core 521, a second insulator 522 wrapped around the second core 521, a second shielding layer 523 (such as a shielding braid) wrapped around the second insulator 522, and a second insulation skin 524 wrapped around the second shielding layer 523. The plurality of cables 5 include the first cable 51 and the second cable 52.

Referring to FIG. 26 to FIG. 32, in one embodiment of the present disclosure, the electrical connector 100 further includes at least one ground sheet 4 mounted to the conductive housing 1. The ground sheet 4 includes a first ground sheet 41 and a second ground sheet 42. In the illustrated embodiment of the present disclosure, two first ground sheets 41 are provided and they are made of metal material. Two second ground sheets 42 are provided and they are made of metal material.

Each first ground sheet 41 is generally U-shaped and includes a first mounting plate 411, a second mounting plate 412 opposite to the first mounting plate 411, a first connecting plate 413 connecting one side of the first mounting plate 411 and one side of the second mounting plate 412, and a first extension plate 414 extending downwardly and backwardly from another side of the second mounting plate 412. The first mounting plate 411 defines a plurality of first mounting positioning holes 4111 that match the first positioning posts 1124.

The first connecting plate 413 abuts against and at least partially covers the first front surface 210 of the first insulating fixing block 21. The first connecting plate 413 is located at a front end of the receiving slot 101 along the first direction A1-A1. When the first mating connector is inserted, the tongue plate may be in contact with the first connecting plate 413 first, thereby facilitating the discharge of static electricity. The second mounting plate 412 is provided with a plurality of first grounding elastic arms 415 which are disposed at intervals along the third direction A3-A3. The first grounding elastic arms 415 are disposed on two sides of the first contact arms 310 of each group of first conductive terminals 31 so as to improve the shielding effect and improve the quality of signal transmission.

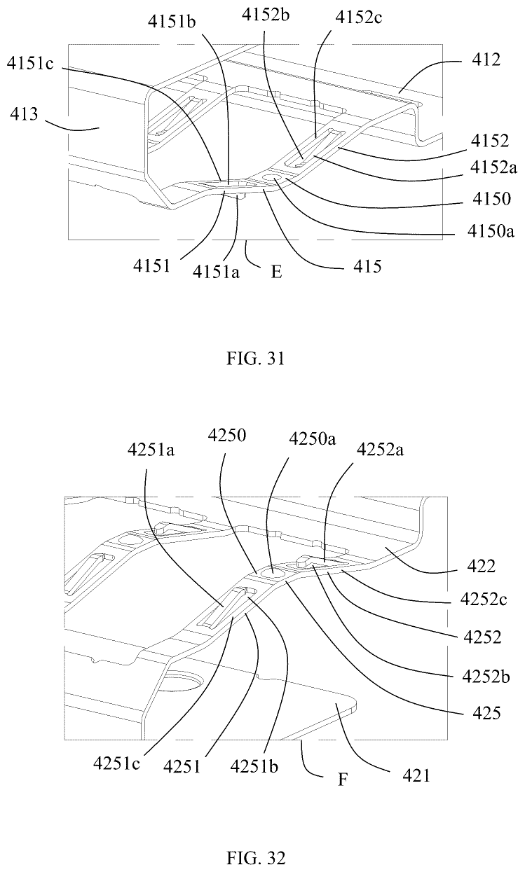

Referring to FIG. 31, the first grounding elastic arm 415 as a whole bulges away from the first mounting plate 411. Specifically, in the illustrated embodiment of the present disclosure, the first grounding elastic arm 415 includes a first intermediate portion 4150, a first elastic arm portion 4151 connecting one end of the first intermediate portion 4150 and the first connecting plate 413, and a second elastic arm portion 4152 connecting another end of the first intermediate portion 4150 and the first extension plate 414. In one embodiment of the present disclosure, the first intermediate portion 4150 includes a first dimple 4150a protruding into the receiving slot 101. The first elastic arm portion 4151 is provided with a first contact elastic arm 4151a extending toward the first intermediate portion 4150, and a first relief groove 4151b corresponding to the first contact elastic arm 4151a and providing a deformation space for the first contact elastic arm 4151a. The second elastic arm portion 4152 is provided with a second contact elastic arm 4152a extending toward the first intermediate portion 4150, and a second relief groove 4152b corresponding to the second contact elastic arm 4152a and providing a deformation space for the second contact elastic arm 4152a. In the illustrated embodiment of the present disclosure, the first contact elastic arm 4151a and the second contact elastic arm 4152a are located on two sides of the first intermediate portion 4150, respectively. The first contact elastic arm 4151a and the second contact elastic arm 4152a are aligned along the first direction A1-A1. A free end of the first contact elastic arm 4151a and a free end of the second contact elastic arm 4152a are both located adjacent to the first intermediate portion 4150. The first contact elastic arm 4151a, the first dimple 4150a and the second contact elastic arm 4152a are all in contact with the corresponding first ground contact pad of the first mating connector. This three-point contact method is beneficial to achieve better shielding effect.

In one embodiment of the present disclosure, the first elastic arm portion 4151 includes a first frame 4151c that is surrounded by all sides. The first relief groove 4151b is a closed groove and is surrounded by the first frame 4151c. The first contact elastic arm 4151a is connected to a wall of the first frame 4151c. The other three walls of the first frame 4151c respectively surround the other three sides of the first contact elastic arm 4151a. In an embodiment of the present disclosure, by arranging the first frame 4151c surrounding the first contact elastic arm 4151a, it can provide better protection for the first contact elastic arm 4151a and prevent the first contact elastic arm 4151a from being excessively deformed.

Similarly, the second elastic arm portion 4152 includes a second frame 4152c that is surrounded by all sides. The second relief groove 4152b is a closed groove and is surrounded by the second frame 4152c. The second contact elastic arm 4152a is connected to a wall of the second frame 4152c. The other three walls of the second frame 4152c respectively surround the other three sides of the second contact elastic arm 4152a. In one embodiment of the present disclosure, by arranging the second frame 4152c surrounding the second contact elastic arm 4152a, it can provide better protection for the second contact elastic arm 4152a and prevent the second contact elastic arm 4152a from being excessively deformed.

In an embodiment of the present disclosure, the first positioning posts 1124 are fixed to the first mounting positioning holes 4111, so that the first mounting plate 411 is fixed to the second upper surface 1121 of the first protruding portion 112. When the first contact elastic arm 4151a, the first intermediate portion 4150 and the second contact elastic arm 4152a are contacted and deformed by the first ground contact pad of the first mating connector, the first extension plate 414 can move appropriately along the first direction A1-A1.

Each second ground sheet 42 is generally U-shaped and includes a third mounting plate 421, a fourth mounting plate 422 opposite to the third mounting plate 421, a second connecting plate 423 connecting one side of the third mounting plate 421 and one side of the fourth mounting plate 422, and a second extension plate 424 extending downwardly and backwardly from another side of the fourth mounting plate 422. The third mounting plate 421 defines a plurality of second mounting positioning holes 4211 that match the second positioning posts 1224.

The second connecting plate 423 abuts against and at least partially covers the second front surface 220 of the second insulating fixing block 22. The second connecting plate 423 is located at the front end of the receiving slot 101 along the first direction A1-A1. When the first mating connector is inserted, the tongue plate may be in contact with the second connecting plate 423 first, thereby facilitating the discharge of static electricity. The fourth mounting plate 422 is provided with a plurality of second grounding elastic arms 425 which are disposed at intervals along the third direction A3-A3. The second grounding elastic arms 425 are disposed on two sides of the second contact arms 320 of each group of second conductive terminals 32, respectively, so as to improve the shielding effect and improve the quality of signal transmission.

Referring to FIG. 32, the second grounding elastic arm 425 bulges away from the third mounting plate 421 as a whole. Specifically, in the illustrated embodiment of the present disclosure, the second grounding elastic arm 425 includes a second intermediate portion 4250, a third elastic arm portion 4251 connecting one end of the second intermediate portion 4250 and the second connecting plate 423, and a fourth elastic arm portion 4252 connecting another end of the second intermediate portion 4250 and the second extension plate 424. In one embodiment of the present disclosure, the second intermediate portion 4250 includes a second dimple 4250a protruding into the receiving slot 101. The third elastic arm portion 4251 includes a third contact elastic arm 4251a extending toward the second intermediate portion 4250, and a third relief groove 4251b corresponding to the third contact elastic arm 4251a and providing a deformation space for the third contact elastic arm 4251a. The fourth elastic arm portion 4252 includes a fourth contact elastic arm 4252a extending toward the second intermediate portion 4250, and a fourth relief groove 4252b corresponding to the fourth contact elastic arm 4252a and providing a deformation space for the fourth contact elastic arm 4252a. In the illustrated embodiment of the present disclosure, the third contact elastic arm 4251a and the fourth contact elastic arm 4252a are located on two sides of the second intermediate portion 4250, respectively. The third contact elastic arm 4251a and the fourth contact elastic arm 4252a are aligned along the first direction A1-A1. A free end of the third contact elastic arm 4251a and a free end of the fourth contact elastic arm 4252a are both adjacent to the second intermediate portion 4250. The third contact elastic arm 4251a, the second dimple 4250a and the fourth contact elastic arm 4252a are all in contact with the second ground contact pad of the first mating connector. This three-point contact method is beneficial to achieve better shielding effect.

In one embodiment of the present disclosure, the third elastic arm portion 4251 includes a third frame 4251c that is surrounded by all sides. The third relief groove 4251b is a closed groove and is surrounded by the third frame 4251c. The third contact elastic arm 4251a is connected to a wall of the third frame 4251c. The other three walls of the third frame 4251c respectively surround the other three sides of the third contact elastic arm 4251a. In one embodiment of the present disclosure, by arranging the third frame 4251c surrounding the third contact elastic arm 4251a, it can provide better protection for the third contact elastic arm 4251a and prevent the third contact elastic arm 4251a from being excessively deformed.

Similarly, the fourth elastic arm portion 4252 includes a surrounding fourth frame 4252c. The fourth relief groove 4252b is a closed groove and is surrounded by the fourth frame 4252c. The fourth contact elastic arm 4252a is connected to a wall of the fourth frame 4252c. The other three walls of the fourth frame 4252c respectively surround the other three sides of the fourth contact elastic arm 4252a. In one embodiment of the present disclosure, by arranging the fourth frame 4252c surrounding the fourth contact elastic arm 4252a, it can provide better protection for the fourth contact elastic arm 4252a and prevent the fourth contact elastic arm 4252a from being excessively deformed.

In an embodiment of the present disclosure, the second positioning posts 1224 are fixed in the second mounting positioning holes 4211, so that the third mounting plate 421 is fixed to the fourth lower surface 1222 of the second protruding portion 122. When the third contact elastic arm 4251a, the second intermediate portion 4250 and the fourth contact elastic arm 4252a are contacted and deformed by the second ground contact pad of the first mating connector, the second extension plate 424 can move appropriately along the first direction A1-A1.

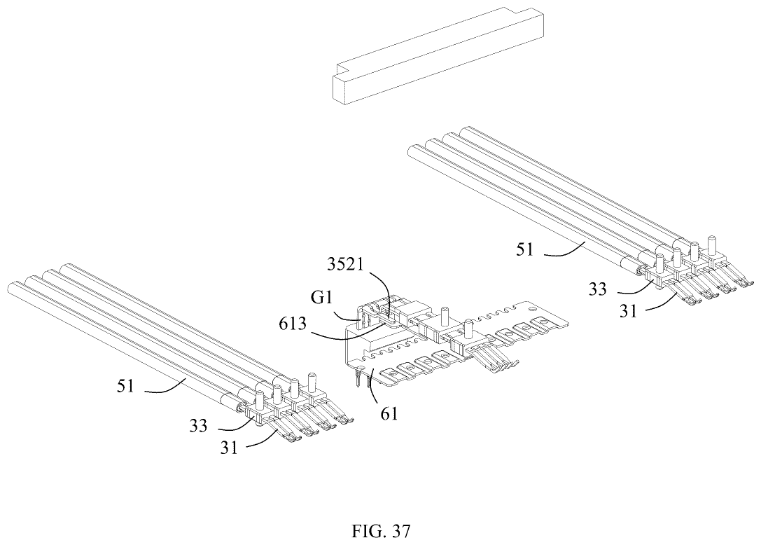

Referring to FIG. 37 to FIG. 45, in the illustrated embodiment of the present disclosure, the first module M1 further includes a first shielding plate 61 installed on the first conductive housing 11. In an embodiment of the present disclosure, the first shielding plate 61 is a metal shielding plate. The first shielding plate 61 includes a first main body portion 611 and a first plate-shaped extension portion 613 extending from the first main body portion 611. The first main body portion 611 includes a plurality of first stamped portions 612 that are integrally stamped from the first main body portion 611. Each first stamped portion 612 defines a first positioning through hole 6121 extending through the first stamped portion 612 along the second direction A2-A2. The first main body portion 611 further includes a plurality of first notches 6111 extending through a side edge of the first main body portion 611 and a plurality of first positioning grooves 6112 extending through the side edge. The plurality of first notches 6111 and the plurality of first positioning grooves 6112 are spaced apart along the third direction A3-A3. The first notches 6111 and the first positioning grooves 6112 are alternately arranged along the third direction A3-A3. The first shielding plate 61 is able to form a surrounding shielding structure together with the first conductive housing 11, thereby improving the shielding effect. The first positioning groove 6112 cooperates with the first positioning block 1141 to achieve positioning. The first notch 6111 corresponds to the first shielding layer 513 of the first cable 51. The first notch 6111 is configured to be filled with solder so that the first main body portion 611 and the first shielding layer 513 can be fixed by soldering, thereby helping to further improve the ground shielding effect. The first positioning through hole 6121 matches the first positioning protruding post 332.

In the illustrated embodiment of the present disclosure, the first plate-shaped extension portion 613 is generally T-shaped and defines at least one first positioning through hole 6131. The first positioning protruding post 33a11 passes through the first positioning through hole 6131 to achieve assembly positioning. The first shielding plate 61 is at least partially supported on the first insulating block 33a1.

The first plate-shaped extension portion 613 of the first shielding plate 61 is in contact with the first abutting portion 3521 of the first ground terminal G1 and the second abutting portion 3522 of the second ground terminal G2, so that the first shielding plate 61 can be grounded with the circuit board 400 through the first mounting tail portion 351 of the first ground terminal G1 and the first mounting tail portion 351 of the second ground terminal G2. In an embodiment of the present disclosure, the first plate-shaped extension portion 613 of the first shielding plate 61 is fixed to the first abutting portion 3521 of the first ground terminal G1 and the second abutting portion 3522 of the second ground terminal G2 by soldering or welding. The first shielding plate 61 is not in contact with the first extension portion 3523 of the first board-end additional terminal 350 to prevent short circuit.

In the illustrated embodiment of the present disclosure, the second module M2 further includes a second shielding plate 63 installed on the second conductive housing 12. In an embodiment of the present disclosure, the second shielding plate 63 is a metal shielding plate. The second shielding plate 63 includes a second main body portion 631 and a second plate-shaped extension portion 633 extending from the second main body portion 631. The second main body portion 631 includes a plurality of second stamped portions 632 that are integrally stamped from the second main body portion 631. Each second stamped portion 632 defines a second positioning through hole 6321 extending through the second stamped portion 632 along the second direction A2-A2. The second main body portion 631 further defines a plurality of second notches 6311 extending through a side edge of the second main body portion 631 and a plurality of second positioning grooves 6312 extending through the side edge. The plurality of second notches 6311 and the plurality of second positioning grooves 6312 are spaced apart along the third direction A3-A3. The second notches 6311 and the second positioning grooves 6312 are alternately arranged along the third direction A3-A3. The second shielding plate 63 is able to form a surrounding shielding structure together with the second conductive housing 12, thereby improving the shielding effect. The second positioning groove 6312 cooperates with the second positioning block 1241 to achieve positioning. The second notch 6311 corresponds to the second shielding layer 523 of the second cable 52. The second notch 6311 is configured to be filled with solder so that the second main body portion 631 and the second shielding layer 523 can be fixed by soldering, thereby helping to further improve the ground shielding effect. The second positioning through hole 6321 matches the second positioning protruding post 342.

In the illustrated embodiment of the present disclosure, the second plate-shaped extension portion 633 is generally T-shaped and defines at least one second positioning through hole 6331. The second positioning protruding post 34a11 passes through the second positioning through hole 6331 to achieve assembly positioning. The second shielding plate 63 is at least partially supported on the second insulating block 34a1.

The second plate-shaped extension portion 633 of the second shielding plate 63 is in contact with the third abutting portion 3621 of the third ground terminal G3 and the fourth abutting portion 3622 of the fourth ground terminal G4, so that the second shielding plate 63 can be grounded with the circuit board 400 through the second mounting tail portion 361 of the third ground terminal G3 and the second mounting tail portion 361 of the fourth ground terminal G4. In an embodiment of the present disclosure, the second plate-shaped extension portion 633 of the second shielding plate 63 is fixed to the third abutting portion 3621 of the third ground terminal G3 and the fourth abutting portion 3622 of the fourth ground terminal G4 by soldering or welding. The second shielding plate 63 is not in contact with the second extension portion 3623 of the second board-end additional terminal 360 to prevent short circuit.

When assembling the electrical connector 100, firstly, the first insulating fixing block 21 is fixed in the first filling grooves 1123, and the second insulating fixing block 22 is fixed in the second filling grooves 1223.

Then, the first terminal modules 31a and the second terminal modules 32a are installed in the corresponding first terminal module installation slots 113 and the second terminal installation slots 123 along the second direction A2-A2. At this time, the first holding block 33 is fixed in the corresponding first terminal module installation slot 113, the first fixing portions 311 of the first conductive terminals 31 are disposed overhead in the corresponding first terminal module installation slot 113, in order to avoid short circuit due to contact with the first conductive housing 11. The first contact arm 310 of the first signal terminal S1 at least partially extends into the first slit 211 of the first insulating fixing block 21. The first contact arm 310 of the second signal terminal S2 at least partially extends into the second slit 212 of the first insulating fixing block 21. Similarly, the second holding block 341 is fixed in the corresponding second terminal module installation slot 123, the second fixing portions 321 of the second conductive terminal 32 are disposed overhead in the second terminal module installation slot 123, in order to avoid short circuit due to contact with the second conductive housing 12. The second contact arm 320 of the third signal terminal S3 at least partially extends into the third slit 221 of the second insulating fixing block 22. The second contact arm 320 of the fourth signal terminal S4 at least partially extends into the fourth slit 222 of the second insulating fixing block 22.

Then, the first cables 51 and the second cables 52 are installed into the corresponding first terminal module installation slots 113 and the second terminal module installation slots 123, respectively. The first core 511 of the first cable 51 is in contact with the first tail portion 313 of the first conductive terminal 31. The second core 521 of the second cable 52 is in contact with the second tail portion 323 of the second conductive terminal 32.

In the illustrated embodiment of the present disclosure, the first cables 51 and the second cables 52 are inserted into the corresponding first terminal module installation slots 113 and the second terminal module installation slots 123, respectively. The first core 511 of the first cable 51 is located at a bottom of the first tail portion 313 of the first conductive terminal 31. The second core 521 of the second cable 52 is located on a top of the second tail portion 323 of the second conductive terminal 32. Preferably, in an embodiment of the present disclosure, the first core 511 of the first cable 51 and the first tail 313 of the first conductive terminal 31 are fixed by soldering or welding. The second core 521 of the second cable 52 and the second tail 323 of the second conductive terminal 32 are fixed by soldering or welding.

Then, the first shielding plate 61 and the second shielding plate 63 are installed on the first conductive housing 11 and the second conductive housing 12, respectively.

Then, the first ground sheet 41 and the second ground sheet 42 are installed on the first conductive housing 11 and the second conductive housing 12, respectively.

Then, the first conductive housing 11 and the second conductive housing 12 are attached to each other. The first base portion 111 and the second base portion 121 correspond along the top-bottom direction. The first protruding portion 112 and the second protruding portion 122 correspond along the top-bottom direction. In the second direction A2-A2, the first shielding plate 61 and the second shielding plate 63 are located between the plurality of first conductive terminals 31 and the plurality of second conductive terminals 32 to reduce crosstalk between the first conductive terminals 31 and the second conductive terminals 32. Besides, in order to further increase the bonding force of the first conductive housing 11 and the second conductive housing 12, the first conductive housing 11 and the second conductive housing 12 are soldered or welded at the joint position. When the first conductive housing 11 and the second conductive housing 12 are fixed, the receiving slot 101 for receiving the first mating connector is formed between the first protruding portion 112 and the second protruding portion 122.

It is understandable to those skilled in the art that the order of the steps in the above assembly method can be flexibly adjusted as needed, and will not be described again in the present disclosure.

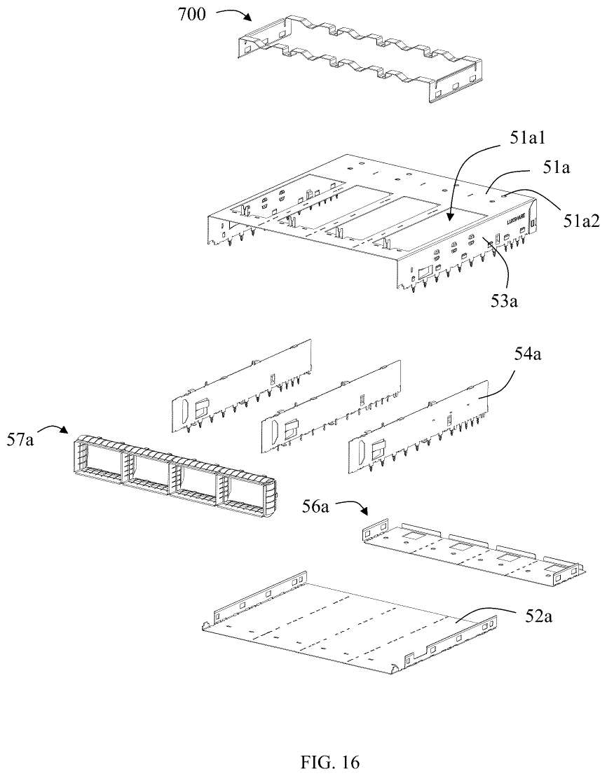

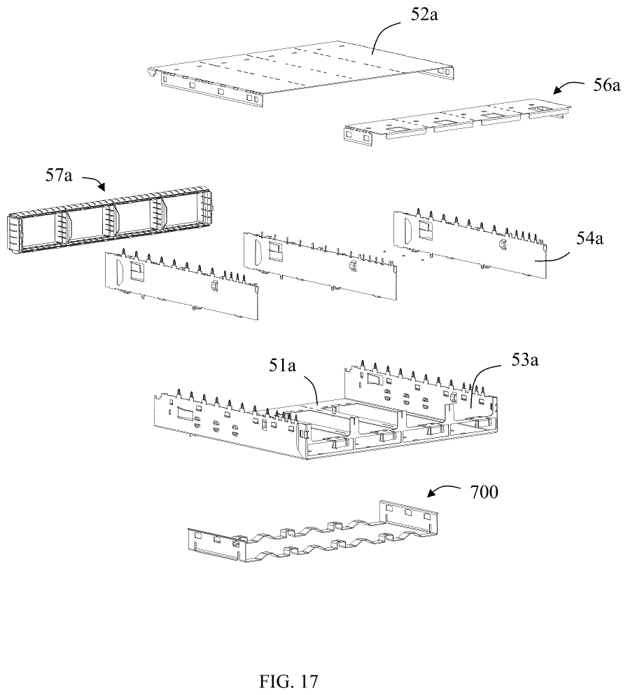

As shown in FIG. 1 to FIG. 17, the connector assembly of the present disclosure further includes a shielding cage 500. The shielding cage 500 is installed and fixed to the circuit board 400. In the illustrated embodiment of the present disclosure, the shielding cage 500 is made of metal material to provide a relatively good shielding effect. In the illustrated embodiment of the present disclosure, the shielding cage 500 includes a plurality of receiving cavities 50a which are arranged side by side along the third direction A3-A3. Corresponding to each receiving cavity 50a, the shielding cage 500 includes a first wall portion 51a (for example, a top wall), a second wall portion 52a (for example, a bottom wall) disposed opposite to the first wall portion 51a, a third wall portion 53a (for example, a left side wall), a fourth wall portion 54a (for example, a right side wall) disposed opposite to the third wall portion 53a, and a fifth wall portion 55a (for example, a rear wall). In the illustrated embodiment of the present disclosure, the first wall portion 51a, the second wall portion 52a, the third wall portion 53a, the fourth wall portion 54a and the fifth wall portion 55a are jointly enclosed to form a receiving cavity 50a.

The first wall portion 51a defines an opening 51a1 that extends through the first wall portion 51a and is in communication with the receiving cavity 50a.

The shielding cage 500 further defines at least one positioning hole 51a2. The at least one positioning hole 51a2 matches the at least one positioning protrusion 71 of the electrical connector 100. In the illustrated embodiment of the present disclosure, the at least one positioning hole 51a2 includes a plurality of first positioning holes 51a21 provided on the first wall portion 51a and extending through the first wall portion 51a along the second direction A2-A2. In the illustrated embodiment of the present disclosure, two first positioning holes 51a21 are provided and are spaced apart along the first direction A1-A1. The first positioning hole 51a21 is a round hole and matches the first positioning protrusion 711.

The second wall portion 52a defines a plurality of first slits 52a1 and a plurality of second slits 52a2. The plurality of first slits 52a1 are arranged in a row along the first direction A1-A1. The plurality of second slits 52a2 are arranged in another row along the first direction A1-A1.

Furthermore, in the illustrated embodiment of the present disclosure, the second wall portion 52a defines a mounting opening 52a3 configured to mount the electrical connector 100. The shielding cage 500 includes a mounting wall 56a that at least partially covers the mounting opening 52a3. The positioning holes 51a2 include a plurality of second positioning holes 51a22 provided on the mounting wall 56a and extending through the mounting wall 56a along the second direction A2-A2. In the illustrated embodiment of the present disclosure, two second positioning holes 51a22 are provided and are spaced apart along the third direction A3-A3. The second positioning hole 51a22 is a round hole and matches the second positioning protrusion 712.

The mounting wall 56a includes a mounting portion 56a1 disposed opposite to the first wall portion 51a, a first retaining portion 56a2 bent from one side of the mounting portion 56a1, a second retaining portion 56a3 bent from another side of the mounting portion 56a1, and an abutting portion 56a4 bent from one end of the mounting portion 56a1. The abutting portion 56a4 supports the electrical connector 100.

The third wall portion 53a is provided with a plurality of first pressing feet 53a1 extending downwardly and passing through the plurality of first slits 52a1. The first pressing foot 53a1 defines a fisheye hole, so that the first pressing foot 53a1 has a certain elastic deformation ability. The first pressing foot 53a1 is configured to pass through the first slit 52a1 and be inserted into the first mating hole 401 of the circuit board 400 so as to be fixed to the circuit board 400 and achieve grounding.

The fourth wall portion 54a defines a plurality of second pressing feet 54a1 extending downwardly and passing through the plurality of second slits 52a2. The second pressing foot 54a1 defines a fisheye hole, so that the second pressing foot 54a1 has a certain elastic deformation ability. The second pressing foot 54a1 is configured to pass through the second slit 52a2 and be inserted into the second mating hole 402 of the circuit board 400 so as to be fixed to the circuit board 400 and achieve grounding.

The fifth wall portion 55a defines an opening 55a1 extending through the fifth wall portion 55a along the first direction A1-A1. The opening 55a1 is in communication with the receiving cavity 50a. The electrical connector 100 at least partially passes through the opening 55a1 and extend beyond the fifth wall portion 55a.

In the illustrated embodiment of the present disclosure, the fifth wall portion 55a defines at least one heat dissipation opening 55a2 communicating with the receiving cavity 50a along the first direction A1-A1. The heat dissipation opening 55a2 extends through the fifth wall portion 55a along the first direction A1-A1.

Referring to FIG. 10, in the illustrated embodiment of the present disclosure, the shielding cage 500 further includes a connecting wall 58 connected to the fifth wall portion 55a and a holding arm 59 connected to the connecting wall 58. In the illustrated embodiment of the present disclosure, the connecting wall 58 extends along the first direction A1-A1. The holding arm 59 extends along the second direction A2-A2. The connecting wall 58 is located between the fifth wall portion 55a and the holding arm 59. The fifth wall portion 55a and the holding arm 59 are parallel to each other. The connecting wall 58 is perpendicular to the fifth wall portion 55a and the holding arm 59.

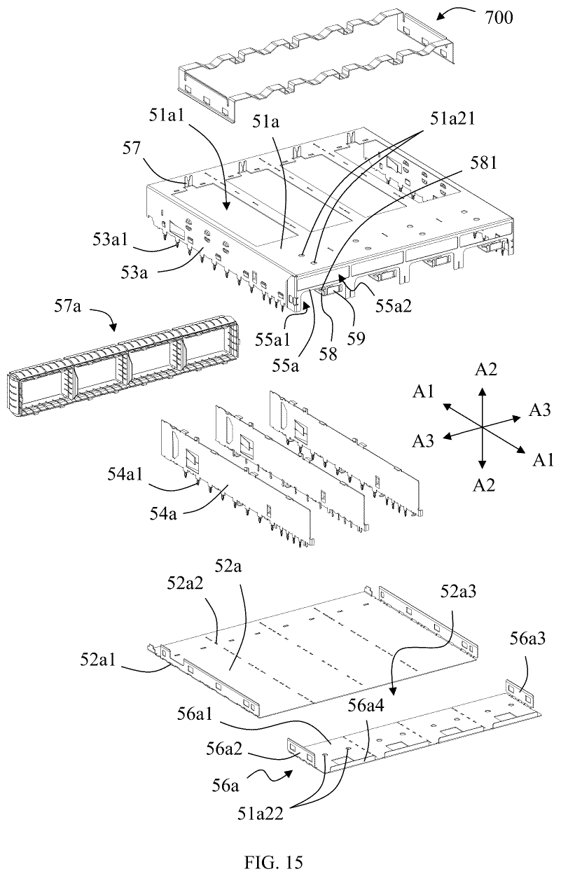

In the illustrated embodiment of the present disclosure, the connecting wall 58 defines at least one opening 581 extending through the connecting wall 58 along the second direction A2-A2 (as shown in FIG. 15). The outer insulating housing 7 further includes at least one mounting post 713. The mounting post 713 passes through the opening 581 to achieve fixation. In an embodiment of the present disclosure, the mounting post 713 is fixed in the opening 581 by heat melting, so that the connecting wall 58 and the electrical connector 100 are integrated into a whole.

The shielding cage 500 further includes a plurality of grounding elastic pieces 57a configured to abut against the mating connector in order to increase the holding force and improve the grounding effect.

In addition, in the illustrated embodiment of the present disclosure, the connector assembly further includes a heat dissipation module 600 installed on the shielding cage 500, a retaining piece 700 for reliably fixing the heat dissipation module 600 to the shielding cage 500, and a plurality of light guide pipe 800.

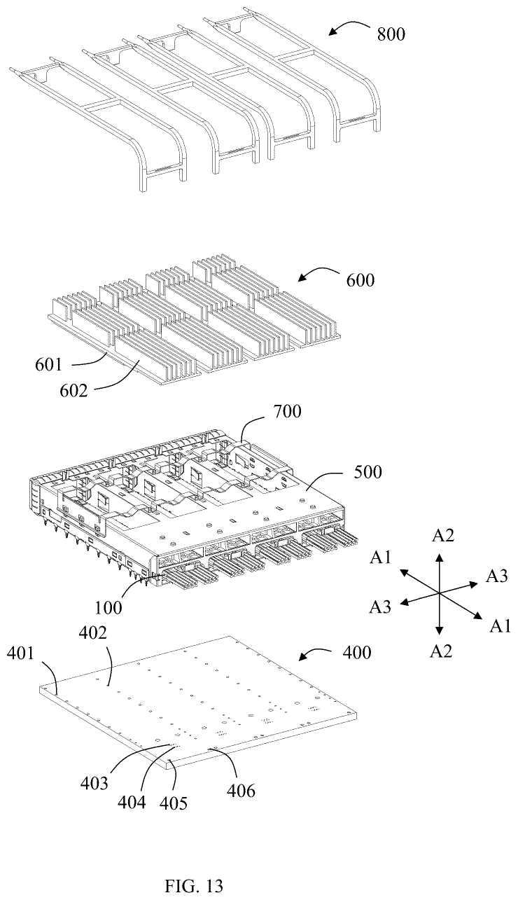

Referring to FIG. 13, the heat dissipation module 600 includes a heat dissipation base plate 601 and a plurality of heat dissipation fins 602 protruding from the heat dissipation base plate 601. The heat dissipation base plate 601 at least partially passes through the opening 51a1 to protrude into the receiving cavity 50a. The heat dissipation base plate 601 is configured to contact the mating connector to transfer heat from the heat dissipation base plate 601 to the heat dissipation fins 602, and then dissipate the heat to the outside.

Referring to FIG. 10, in the illustrated embodiment of the present disclosure, the holding arm 59 includes a first retaining arm 591, a second retaining arm 592, and an inserting plate portion 593 located between the first retaining arm 591 and the second retaining arm 592. The first retaining arm 591, the inserting plate portion 593 and the second retaining arm 592 are arranged in sequence at intervals along the third direction A3-A3. Specifically, the first retaining arm 591 is provided with a first hook portion 5911. The second retaining arm 592 is provided with a second hook portion 5921. The first hook portion 5911 and the second hook portion 5921 protrude in opposite directions.

Besides, as shown in FIG. 12, the shielding cage 500 further includes a bracket portion 57 integrally bent from the first wall portion 51a. The bracket portion 57 extends along the second direction A2-A2 and is perpendicular to the first wall portion 51a. In the illustrated embodiment of the present disclosure, the bracket portion 57 includes a first bracket arm 571, a second bracket arm 572, and a mounting slit 570 located between the first bracket arm 571 and the second bracket arm 572.

Specifically, in the illustrated embodiment of the present disclosure, the first bracket arm 571 is provided with a first guide surface 5711 at an end thereof and a first recess 5712 located at a lower side of the first guide surface 5711 along the second direction A2-A2. The second bracket arm 572 is provided with a second guide surface 5721 at an end thereof and a second recess 5722 located at a lower side of the second guide surface 5721 along the second direction A2-A2. The first guide surface 5711 and the second guide surface 5721 together form a bell mouth 573 for guiding the installation of the light guide pipe 800. The first recess 5712 and the second recess 5722 form a buffer opening 574. A size of the buffer opening 574 along the third direction A3-A3 is larger than a size of the mounting slit 570 along the third direction A3-A3.

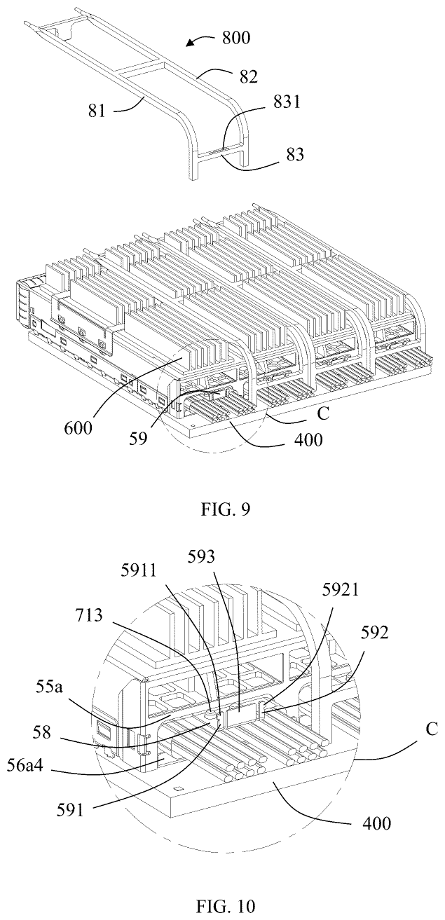

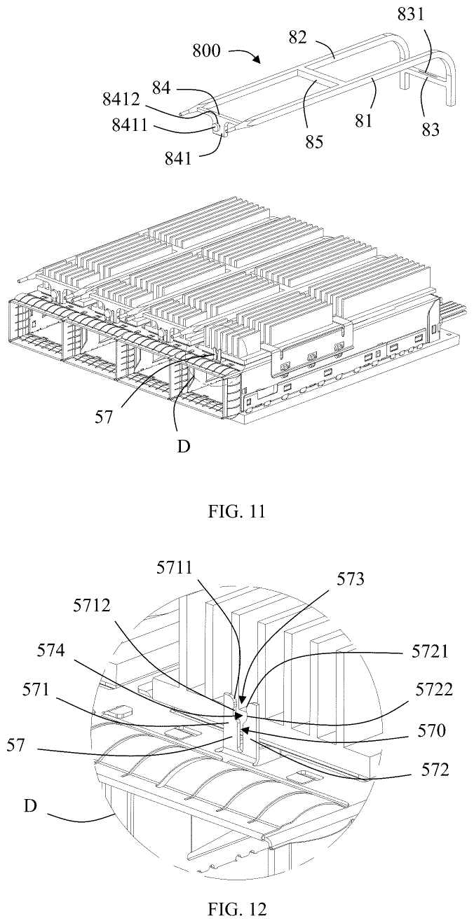

Referring to FIG. 9 and FIG. 11, each light guide pipe 800 includes a first pipe body portion 81, a second pipe body portion 82, a first connecting portion 83 connecting the first pipe body portion 81 and the second pipe body portion 82, a second connecting portion 84 connecting the first pipe body portion 81 and the second pipe body portion 82, and a third connecting portion 85 connecting the first pipe body portion 81 and the second pipe body portion 82. The first pipe body portion 81 and the second pipe body portion 82 are both L-shaped. The first connecting portion 83, the second connecting portion 84 and the third connecting portion 85 are spaced apart along the first direction A1-A1. The first connecting portion 83 defines a mounting slot 831. The holding arm 59 is at least partially inserted into the mounting slot 831 so as to fix the light guide pipe 800. Specifically, the first hook portion 5911 and the second hook portion 5921 are both locked with the first connecting portion 83. The inserting plate portion 593 is at least partially inserted into the mounting slot 831. In the illustrated embodiment of the present disclosure, the first retaining arm 591, the inserting plate portion 593 and the second retaining arm 592 all pass through the first connecting portion 83 from the mounting slot 831.

The second connecting portion 84 includes an extending protruding portion 841 protruding along the second direction A2-A2. The extending protruding portion 841 includes a protruding column portion 8411 and a neck portion 8412 connected to the protruding column portion 8411. The neck portion 8412 is contracted compared to the protruding column portion 8411.

In assembly, the neck portion 8412 of the light guide pipe 800 is firstly assembled into the buffer opening 574 under the guidance of the bell mouth 573. Then, a pressing force is applied to the light guide pipe 800 so that the neck portion 8412 is tightly clamped from the buffer opening 574 into the mounting slit 570 to achieve installation and fixation. The protruding column portion 8411 protrudes beyond the bracket portion 57 along the first direction A1-A1. At the same time, the holding arm 59 of the light guide pipe 800 passes through the mounting slot 831 to fix the light guide pipe 800.

After the light guide pipe 800 is assembled in place, the first pipe body portion 81 and the second pipe body portion 82 are located two sides of the cables 5 (including the first cables 51 and the second cables 52), respectively, so as not to affect the arrangement of the cables 5. The heat dissipation fins 602 protrude beyond the first pipe body portion 81 and the second pipe body portion 82 along the second direction A2-A2. The first pipe body portion 81 and the second pipe body portion 82 are located on two sides of the heat dissipation fins 602, respectively, along the third direction A3-A3. The first pipe body portion 81 and the second pipe body portion 82 correspond to the first light-emitting element 405 and the second light-emitting element 406, respectively, so that the light generated by the first light-emitting element 405 and the second light-emitting element 406 is displayed at a mating end of the connector assembly through the first pipe body portion 81 and the second pipe body portion 82 to facilitate identification of the working status of the connector assembly.

When assembling the shielding cage 500 and the electrical connector 100, firstly, the electrical connector 100 is installed into the shielding cage 500 from the mounting opening 52a3. The positioning portion 7112 of the first positioning protrusion 711 is inserted into and positioned in the first positioning hole 51a21. The support portion 7111 supports the first wall portion 51a. Then, the mounting wall 56a is fastened. The second positioning protrusion 712 is inserted into and positioned in the second positioning hole 51a22. The abutting portion 56a4 supports the electrical connector 100. Then, the shielding cage 500 is fixed on the circuit board 400. In an embodiment of the present disclosure, in order to further increase the bonding strength between the electrical connector 100 and the shielding cage 500, after the positioning portion 7112 of the first positioning protrusion 711 is inserted and positioned in the first positioning hole 51a21, it is further fixed with the shielding cage 500 by heat fusion. Similarly, after the second positioning protrusion 712 is inserted and positioned in the second positioning hole 51a22, it is further fixed with the shielding cage 500 by heat fusion.

Compared with the prior art, the connector assembly of the present disclosure includes the electrical connector 100 and the shielding cage 500. The electrical connector 100 and the shielding cage 500 have at least one positioning protrusion 71 and at least one positioning hole 51a2 that cooperate with each other. The positioning protrusion 71 is inserted into the positioning hole 51a2. With this arrangement, the present disclosure is able to effectively fix the position of the electrical connector 100 and prevent the electrical connector 100 from moving with respect to the shielding cage 500. In the illustrated embodiment of the present disclosure, the positioning protrusion 71 is provided on the electrical connector 100, and the positioning hole 51a2 is provided on the shielding cage 500. The positioning protrusion 71 can be integrally formed with the outer insulating housing 7 or provided separately. Of course, it is understandable to those skilled in the art that in other embodiments of the present disclosure, the positioning protrusion 71 may also be provided on the shielding cage 500. At this time, the positioning hole 51a2 is provided on the electrical connector 100. The positioning protrusion 71 can be integrally formed with the shielding cage 500 or provided separately. In addition, in order to improve heat dissipation, the shielding cage 500 of the present disclosure defines at least one heat dissipation opening 55a2. By providing the support portion 7111 to support the first wall portion 51a, the present disclosure is able to compensate for the decrease in structural strength caused by the provision of the heat dissipation opening 55a2. Besides, the conductive terminals 3 of the electrical connector 100 in the illustrated embodiment of the present disclosure include the cable terminals and the board-end terminals. This hybrid terminal arrangement often brings inconvenience in the arrangement and installation of peripheral components. In the illustrated embodiment of the present disclosure, the light guide pipe 800 is fixed by at least partially inserting the holding arm 59 into the mounting slot 831, thereby simplifying the fixing structure. In addition, the present disclosure disposes the first shielding plate 61 to be in contact with the first ground terminal G1 and the second ground terminal G2, so that the first shielding plate 61 can be brought to achieve grounding with the circuit board 400 through the first mounting tail portion 351 of the first ground terminal G1 and the first mounting tail portion 351 of the second ground terminal G2. As a result, the structural design of the first ground terminal G1 and the second ground terminal G2 themselves is simplified.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A connector assembly, comprising:
an electrical connector, the electrical connector comprising:
a housing, the housing defining a receiving slot;
a plurality of conductive terminals, the plurality of conductive terminals being mounted to the housing; and
a cable, the cable being electrically connected to the conductive terminals;
a shielding cage, the shielding cage being configured to be mounted to a circuit board, the shielding cage defining a receiving cavity communicating with the receiving slot along a first direction; the receiving cavity and the receiving slot being configured to jointly receive a mating connector along the first direction; the cable passing out of the shielding cage along the first direction; the shielding cage being provided with a holding arm; and
a light guide pipe, the light guide pipe comprising a first pipe body portion, a second pipe body portion, and a first connecting portion connecting the first pipe body portion and the second pipe body portion; the first pipe body portion and the second pipe body portion being located on two sides of the cable, respectively; the first connecting portion defining a mounting slot; the holding arm being at least partially inserted into the mounting slot so as to fix the light guide pipe.

2. The connector assembly according to claim 1, wherein the holding arm comprises a first retaining arm and a second retaining arm spaced apart from the first retaining arm; the first retaining arm is provided with a first hook portion; the second retaining arm is provided with a second hook portion; the first hook portion and the second hook portion are both locked with the first connecting portion.

3. The connector assembly according to claim 2, wherein the first hook portion and the second hook portion protrude in opposite directions.

4. The connector assembly according to claim 2, wherein the holding arm further comprises an inserting plate portion located between the first retaining arm and the second retaining arm; the first retaining arm, the inserting plate portion and the second retaining arm are arranged at intervals in sequence; the inserting plate portion is at least partially inserted into the mounting slot.

5. The connector assembly according to claim 4, wherein the first retaining arm, the inserting plate portion and the second retaining arm all pass through the first connecting portion from the mounting slot.

6. The connector assembly according to claim 1, wherein the light guide pipe comprises a second connecting portion which connects the first pipe body portion and the second pipe body portion; the second connecting portion comprises an extending protruding portion which protrudes along a second direction perpendicular to the first direction; the extending protruding portion comprises a protruding column portion and a neck portion connected to the protruding column portion;
the shielding cage comprises a bracket portion; the bracket portion comprises a first bracket arm, a second bracket arm, and a mounting slit located between the first bracket arm and the second bracket arm; the neck portion is tightly clamped in the mounting slit; the protruding column portion protrudes beyond the bracket portion along the first direction.

7. The connector assembly according to claim 6, wherein the first bracket arm is provided with a first guide surface disposed at an end thereof and a first recess located at a lower side of the first guide surface along the second direction; the second bracket arm is provided with a second guide surface disposed at an end thereof and a second recess located at a lower side of the second guide surface along the second direction; the first guide surface and the second guide surface form a bell mouth for guiding insertion of the neck portion; the first recess and the second recess form a buffer opening; a size of the buffer opening along a third direction is larger than a size of the mounting slit along the third direction; the third direction is perpendicular to the first direction and the second direction.

8. The connector assembly according to claim 1, wherein the shielding cage comprises a connecting wall connected to the holding arm; the connecting wall defines at least one opening;
the electrical connector comprises an outer insulating housing fixed on the housing; the outer insulating housing is provided with at least one mounting post passing through the at least one opening.

9. The connector assembly according to claim 8, wherein the mounting post is fixed in the at least one opening through heat fusion, so that the connecting wall and the electrical connector are integrated into a whole.

10. The connector assembly according to claim 1, wherein the electrical connector and the shielding cage are provided with at least one positioning protrusion and at least one positioning hole that cooperate with each other along a second direction; the at least one positioning protrusion is inserted into the at least one positioning hole; the second direction is perpendicular to the first direction.

11. The connector assembly according to claim 10, wherein the shielding cage comprises a first wall portion, a second wall portion disposed opposite the first wall portion, a third wall portion, and a fourth wall portion disposed opposite to the third wall portion; the receiving cavity is circumferentially surrounded by at least the first wall portion, the third wall portion, the second wall portion and the fourth wall portion.

12. The connector assembly according to claim 11, wherein the electrical connector comprises an outer insulating housing fixed on the housing; the at least one positioning protrusion comprises a first positioning protrusion provided on the outer insulating housing; the first positioning protrusion comprises a positioning portion located at an end of the first positioning protrusion;
the at least one positioning hole comprises a first positioning hole provided on the first wall portion and extending through the first wall portion along the second direction;
the positioning portion is inserted into the first positioning hole.

13. The connector assembly according to claim 12, wherein two first positioning protrusions are provided and are spaced apart along the first direction;
two first positioning holes are provided and are spaced apart along the first direction.

14. The connector assembly according to claim 12, wherein the first positioning protrusion comprises a support portion connected to the positioning portion, and the support portion supports the first wall portion along the second direction.

15. The connector assembly according to claim 12, wherein the at least one positioning protrusion comprises a second positioning protrusion provided on the outer insulating housing; the second positioning protrusion is arranged opposite to the first positioning protrusion along the second direction;
the second wall portion defines a mounting opening configured to mount the electrical connector;
the shielding cage comprises a mounting wall that at least partially covers the mounting opening; the at least one positioning hole comprises a second positioning hole provided on the mounting wall and extending through the mounting wall along the second direction; the second positioning protrusion is inserted into the second positioning hole.

16. The connector assembly according to claim 15, wherein two second positioning protrusions are provided and are spaced apart along the third direction perpendicular to the first direction and the second direction;
two second positioning holes are provided and are spaced apart along the third direction.

17. The connector assembly according to claim 15, wherein the mounting wall comprises a mounting portion disposed opposite the first wall portion, a first retaining portion bent from one side of the mounting portion, a second retaining portion bent from another side of the mounting portion, and an abutting portion bent from one end of the mounting portion; the abutting portion supports the electrical connector.

18. The connector assembly according to claim 11, wherein the shielding cage comprises a fifth wall portion located at an end of the receiving cavity along the first direction; the fifth wall portion defines an opening, and the electrical connector at least partially passes through the opening;
the fifth wall portion defines at least one heat dissipation opening communicating with the receiving cavity along the first direction; the heat dissipation opening extends through the fifth wall portion along the first direction.

19. The connector assembly according to claim 1, wherein the electrical connector further comprises a first module and a second module mated with the first module; the first module comprises:
a first conductive housing;
a first terminal module at least partially disposed in the first conductive housing; the first terminal module comprises a plurality of first conductive terminals which are not in contact with the first conductive housing; each first conductive terminal comprises a first contact arm comprising a first contact portion;
a plurality of first cables electrically connected to the plurality of first conductive terminals;
the second module comprises:
a second conductive housing;
a second terminal module at least partially disposed in the second conductive housing;
the second terminal module comprises a plurality of second conductive terminals which are not in contact with the second conductive housing; each second conductive terminal comprises a second contact arm comprising a second contact portion; and
a plurality of second cables electrically connected to the plurality of second conductive terminals;
wherein the housing comprises the first conductive housing and the second conductive housing; the first conductive housing of the first module and the second conductive housing of the second module together form the receiving slot; the conductive terminals comprise the first conductive terminals and the second conductive terminals; the cable comprises the first cables and the second cables; both the first contact portion and the second contact portion at least partially protrude into the receiving slot to make electrical contact with the mating connector.

20. The connector assembly according to claim 1, further comprising a heat dissipation module mounted on the shielding cage; wherein the heat dissipation module comprises a heat dissipation base plate and a plurality of heat dissipation fins protruding from the heat dissipation base plate; the heat dissipation base plate at least partially protrudes into the receiving cavity; the heat dissipation fins protrude beyond the first pipe body portion and the second pipe body portion in a second direction; the first pipe body portion and the second pipe body portion are located on two sides of the heat dissipation fins, respectively, along a third direction; each two of the first direction, the second direction and the third direction are perpendicular to each other.
